(19) United States
(12) Patent Application Publication
(10) Pub. No.: US 2006/0182995 A1
(43) Pub. Date: Aug. 17, 2006

(54) Biphenyl derivatives and organic electroluminescent devices using the same

(76) Inventors: Seok Chang, Daejeon-si (KR); Ji-Hoon Lee, Chungju-si (KR); Sung-Hwan Lim, Seoul (KR); Das Rupasree Ragini, Suwon-si (KR); Hee-Kyung Kim, Anyang-si (KR); Lyong-Sun Pu, Suwon-si (KR); Jong-Hyoup Lee, Seoul (KR)

Correspondence Address: Robert E. Bushnell, Suite 300, 1522 K Street, N.W., Washington, DC, 20005, US

(21) Appl. No.: 11/334,775

(22) Filed: Jan. 19, 2006

(30) Foreign Application Priority Data
Jan. 19, 2005 (KR) 10-2005-0005022

(51) Int. Cl. H01L 51/54; H05B 33/14; C09K 11/06

(52) U.S. Cl. 428/690; 428/917; 313/504; 548/440; 556/407; 544/102; 544/35; 540/588; 564/434

(57) ABSTRACT

Biphenyl derivatives having four substituents at meta positions of biphenyl structure, which is a core molecular structure, and organic electroluminescent devices using the biphenyl derivatives. The biphenyl derivatives are phosphorescent host compounds having amorphous structures and have excellent thermal stability and high solubility in general organic solvents, is easily to use for solution (or wet) process, and can easily energy-transfer to a metal complex used as dopant. The biphenyl derivatives also can be used as blue host materials of phosphorescent emission layer, hole transporting materials, or a hole injecting materials of an organic electroluminescent device.

### CROSS-REFERENCE TO RELATED PATENT APPLICATIONS AND CLAIM OF PRIORITY

This application claims the benefit of Korean Patent Application No. 10-2005-0005022, filed on Jan. 19, 2005, in the Korean Intellectual Property Office, the disclosure of which is incorporated herein in its entirety by reference.

### BACKGROUND OF THE INVENTION

1. Field of the Invention

The present invention relates to biphenyl derivatives and organo-electroluminescent devices using the same, and more particularly, to biphenyl derivatives that has 4 substituents at meta positions of a biphenyl that is core molecular structure, and an organo-electroluminescent device using the same that is thermally stable and can be manufactured using a solution process.

2. Description of the Related Art

Organic electroluminescent devices (Organic EL devices), which are active-emissive type devices, use a recombination of electrons and holes in a fluorescent or phosphorescent organic layer occurring when a current is applied there. Organic EL devices are lightweight, have wide viewing angles, produce high-quality images, and can be manufactured using simplified processes. In addition, by using organic EL devices, moving images with high color purity can be formed with low consumption power and at a low voltage. Accordingly, organic EL devices are suitable for portable electric applications.

Organic EL devices are categorized into small molecule organic EL devices and polymer EL devices according to a material forming an organic layer.

Small molecule organic EL devices use emissive materials that can be highly purified by train sublimation, and color pixels for the three primary colors can be easily realized in such devices. In this case, however, an organic layer is formed by vacuum deposition, which is not suitable for a large-scale process requiring spin coating and inkjet printing.

In polymer organic EL devices, spin coating or printing can be used to form a thin layer, and thus, manufacturing processes can be simplified and applied to a large-scale process at low costs. However, when polymers are synthesized, they have some structural defects that may promote deterioration can be generated in a molecular chain or residual catalysts, and thus it is difficult to obtain highly purified materials. Therefore, because of these problems, polymer organic EL devices have lower luminous efficiency and shorter device lifetime than small molecule EL devices. Accordingly, there is a need to develop organic EL devices manufactured using wet-processable materials that has high color purity, high efficiency, a simple molecular structure, and reproducibility for synthesis, and can be mass-produced.

Electroluminescent devices emit light according to the following mechanism.

Holes are injected through an anode, and electrons are injected through a cathode. The holes and the electrons are recombined in an emission layer, thus forming excitons. The excitons decay radiatively, thus emitting light that corresponds to a band gap of a material forming the emission layer.

Materials for the emission layers are divided into fluorescent materials using singlet-state excitons and phosphorescent materials using triplet-state excitons. In general, conventional organic EL devices are mainly manufactured using fluorescent materials using singlet-state excitons. In this case, 75% of the generated excitons are not used. Therefore, when the fluorescent material is used as the emissive material, that is, when the emission mechanism of the fluorescent using singlet-state excitons is used, the internal quantum efficiency is at most about 25%. Since the extraction efficiency of light is dependent on the refractive index of a substrate material, the actual internal quantum efficiency is at most about 5%. Because of the low internal quantum efficiency of the singlet-state excitons, many efforts to increase luminous efficiency using triplet-state excitons, which have an internal quantum efficiency of 75% and are generated when hole and electron are recombined, have been made.

In general however, transition from the triplet state to the singlet ground state is a forbidden transition and light is not emitted.

Recently, EL devices manufactured by a phosphorescent material system forming triplet-state excitons have been developed. Such phosphorescent material system can be prepared by doping a metal complex, such as an Ir complex or a Pt complex, on a lower molecular weight or polymer host. The Ir complex can be Ir(ppy)₃ (tris(2-phenyl pyridine) iridium) (see WO2002/15645).

In EL devices using the phosphorescent materials, the efficiency, brightness, and lifetime of the device may vary according to a host material and a metal complex dopant. As a result, the host material must be thermally, and electrically stable.

Examples of conventional phosphorescent host materials include CBP (4,4′-N,N′-dicarbazole-biphenyl) (see JP 63-235946 and Appl. Phys. Lett. 79(13), 2082 (2001)), and m-CP (1,3-di(9H-carbazol-9-yl)benzene) (see Appl. Phys. Lett. 82(15), 2422 (2003)) having a wider band gap than CBP. However, an emission layer that is formed by depositing one of these host materials in a vacuum condition changes from a uniform amorphous state to a crystallized or aggregative state over time. That is, after the deposition, the emission layer become non-uniform, and thus the luminous efficiency and lifetime of the device decrease.

In order to prevent this problem and manufacture an organic EL device with high efficiency, a host material that has excellent morphological stability and is suitable for a large-scale processing must be developed.

### SUMMARY OF THE INVENTION

The present invention provides biphenyl derivatives that does not have a molecular defect, has excellent thermal and morphological stabilities, and can be easily purified and formed into a thin layer by wet process.

The present invention also provides an organic electroluminescent device that is manufactured using the biphenyl derivatives to improve luminosity and efficiency.

According to an aspect of the present invention, there is provided biphenyl derivatives represented by Formula 1: 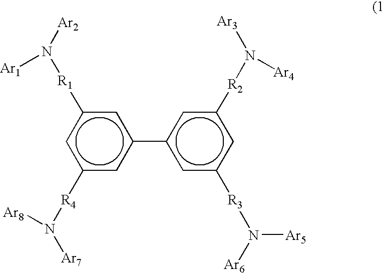
where R₁, R₂, R₃, and R₄ are each independently a single bond; a substituted or non-substituted linear or branched C₁-C₂₀ alkyl group; a substituted or non-substituted C₃-C₂₀ cycloalkyl group; a substituted or non-substituted C₁-C₁₀ alkenyl group; a substituted or non-substituted C₁-C₁₀ alkynyl group; a substituted or non-substituted C₄-C₃₀ aryl group; a substituted or non-substituted C₄-C₃₀ heteroaryl group; or a C₄-C₃₀ aryl group having at least one substituent selected from a halogen atom, a substituted or non-substituted C₁-C₂₀ alkyl halide group, —Si(R)(R′)(R″), a substituted or non-substituted C₁-C₂₀ alkyl group, a substituted or non-substituted C₁-C₂₀ alkoxy group, a substituted or non-substituted C₄-C₃₀ aryl group, a substituted or non-substituted C₄-C₃₀ heteroaryl group, and —N(R)(R′), and

Ar₁, Ar₂, Ar₃, Ar₄, Ar₅, Ar₆, Ar₇, and Ar₈ are each independently H; a substituted or non-substituted linear or branched C₁-C₂₀ alkyl group; a substituted or non-substituted C₃-C₂₀ cycloalkyl group; a substituted or non-substituted C₄-C₃₀ aryl group; a substituted or non-substituted C₄-C₃₀ heteroaryl group; or a C₄-C₃₀ aryl group having at least one substituent selected from the group consisting of a substituted or non-substituted C₁-C₂₀ alkyl halide group, —Si(R)(R′)(R″), a substituted or non-substituted C₁-C₂₀ alkyl group, a substituted or non-substituted C₁-C₂₀alkoxy group, a substituted or non-substituted C₄-C₃₀ aryl group, a substituted or non-substituted C₄-C₃₀ heteroaryl group, and —N(R)(R′), wherein Ar₁ can be connected to Ar₂, Ar₃ can be connected to Ar₄, Ar₅ can be connected to Ar₆, and Ar₇ can be connected to Ar₈; and

R, R′, and R″ are each independently H, a substituted or non-substituted C₁-C₂₀ alkyl group, a substituted or non-substituted C₁-C₂₀ alkoxy group, a substituted or non-substituted C₄-C₃₀ aryl group, or a substituted or non-substituted C₄-C₃₀ heteroaryl group.

According to another aspect of the present invention, there is provided an organic electroluminescent device comprising an organic layer composed of the biphenyl derivatives interposed between a pair of electrodes.

### BRIEF DESCRIPTION OF THE DRAWINGS

A more complete appreciation of the present invention, and many of the above and other features and advantages of the present invention, will be readily apparent as the same becomes better understood by reference to the following detailed description when considered in conjunction with the accompanying drawings in which like reference symbols indicate the same or similar components, wherein:

FIGS. 1A through 1F are sectional views of organic electroluminescent (EL) devices according to embodiments of the present invention;

FIG. 2 illustrates a ¹H NMR spectrum of TCBP represented by Formula A according to an embodiment of the present invention;

FIG. 3 illustrates a ¹³C NMR spectrum of TCBP represented by Formula A according to an embodiment of the present invention;

FIG. 4 illustrates a FT-IR spectrum (on KBr) of TCBP represented by Formula A according to an embodiment of the present invention.

FIG. 5 illustrates thermogravimetric analysis (TGA) curves of a m-CP (1,3-di(9H-carbazol-9-yl)benzene), and 3,3′,5,5′-tetra(9H-carbazol-9-yl)biphenol (TCBP) represented by Formula A according to an embodiment of the present invention;

FIG. 6A illustrates a differential scanning calorimetry (DSC) curve of m-CP;

FIG. 6B illustrates DSC curves of TCBP represented by Formula A according to an embodiment of the present invention;

FIG. 7 illustrates consecutive DSC curves of TCBP represented by Formula A according to an embodiment of the present invention;

FIG. 8 illustrates a UV-Vis spectrum and a photoluminescence (PL) spectrum of TCBP represented by Formula A according to an embodiment of the present invention;

FIG. 9 is an electroluminescent (EL) spectrum of TCBP represented by Formula A according to an embodiment of the present invention;

FIG. 10 is a graph of luminous efficiency of an organic EL device manufactured using TCBP represented by Formula A according to an embodiment of the present invention;

FIG. 11 is a graph of EL intensity of an organic EL device manufactured using TCBP represented by Formula A according to an embodiment of the present invention; and

FIG. 12 is a sectional view of an organic EL device according to an embodiment of the present invention.

### DETAILED DESCRIPTION OF THE INVENTION

A biphenyl derivative represented by Formula 1 has substituted or non-substituted amino groups at 3,3′,5, and 5′ positions of a biphenyl backbone. 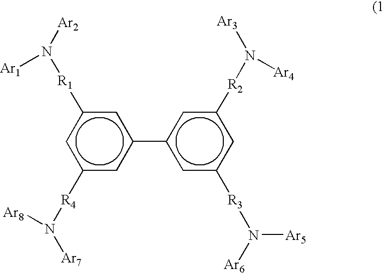
where R₁, R₂, R₃, and R₄ are each independently a single bond; a substituted or non-substituted linear or branched C₁-C₂₀ alkyl group; a substituted or non-substituted C₃-C₂₀ cycloalkyl group; a substituted or non-substituted C₁-C₁₀ alkenyl group; a substituted or non-substituted C₁-C₁₀ alkynyl group; a substituted or non-substituted C₄-C₃₀ aryl group; a substituted or non-substituted C₄-C₃₀ heteroaryl group; or a C₄-C₃₀ aryl group having at least one substituent selected from a halogen atom, a substituted or non-substituted C₁-C₂₀ alkyl halide group, —Si(R)(R′)(R″), a substituted or non-substituted C₁-C₂₀ alkyl group, a substituted or non-substituted C₁-C₂₀ alkoxy group, a substituted or non-substituted C₄-C₃₀ aryl group, a substituted or non-substituted C₄-C₃₀ heteroaryl group, and —N(R)(R′); and

Ar₁, Ar₂, Ar₃, Ar₄, Ar₅, Ar₆, Ar₇, and Ar₈ are each independently H; a substituted or non-substituted linear or branched C₁-C₂₀ alkyl group; a substituted or non-substituted C₃-C₂₀ cycloalkyl group; a substituted or non-substituted C₄-C₃₀ aryl group; a substituted or non-substituted C₄-C₃₀ heteroaryl group; or a C₄-C₃₀ aryl group having at least one substituent selected from a substituted or non-substituted C₁-C₂₀ alkyl halide group, —Si(R)(R′)(R″), a substituted or non-substituted C₁-C₂₀ alkyl group, a substituted or non-substituted C₁-C₂₀ alkoxy group, a substituted or non-substituted C₄-C₃₀ aryl group, a substituted or non-substituted C₄-C₃₀ heteroaryl group, and —N(R)(R′), wherein Ar₁ can be connected to Ar₂, Ar₃ can be connected to Ar₄, Ar₅ can be connected to Ar₆, and Ar₇ can be connected to Ar₈; and

R, R′, and R″ are each independently H, a substituted or non-substituted C₁-C₂₀ alkyl group, a substituted or non-substituted C₁-C₂₀ alkoxy group, a substituted or non-substituted C₄-C₃₀ aryl group, or a substituted or non-substituted C₄-C₃₀ heteroaryl group.

The substituted or non-substituted linear or branched alkyl group or alkoxy group may be a C₁-C₁₂alkyl or alkoxy group, preferably, a C₁-C₇ low alkyl or alkoxy group.

The cycloalkyl group may be a C₃-C₁₂ cycloalkyl group, preferably, a C₃-C₈ cycloalkyl group.

The alkenyl group may be a C₂-C₈ alkenyl group, preferably, a C₂-C₄ alkenyl group.

The alkynyl group may be a C₂-C₈ alkyl group, preferably, a C₂-C₄ alkyl group.

The aryl group may be a C₄-C₃₀ aryl group, preferably, a C₄-C₂₀ aryl group, more preferably, a C₄-C₁₂ aryl group.

The heteroaryl group may be a C₄-C₃₀ heteroaryl group, preferably, a C₄-C₂₀ heteroaryl group, more preferably, a C₄-C₁₂ heteroaryl group having at most three atoms selected from N, S, P, Si, and O at its aromatic ring.

The term ‘substituted alkyl group’, ‘alkoxy group’, ‘cycloalkyl group’, ‘alkenyl group’, ‘alkynyl group’, ‘aryl group’, or ‘heteroaryl group’ indicates that at least one hydrogen of the alkyl group, alkoxy group, cycloalkyl group, alkenyl group, alkynyl group, aryl group, or heteroaryl group is substituted with a compound selected from deuterium, a cyano group, a nitro group, an alkyl group, a cycloalkyl group, an alkoxy group, —SR (wherein R is defined as above), an alkenyl group, an alkynyl group, an aryl group, a heteroaryl group, a halogen atom such as F, Cl, Br, and I, aliphatic amine, aromatic amine, and an aryloxy group.

The biphenyl derivatives do not have a molecular defect (e.g., a structural defect that may be produced by an undesired reaction in a wrong place of a monomer), and can be easily purified and formed into a thin film by solution (or wet) process, although its molecular weight is as small as a few thousand atomic mass units. In particular, in the biphenyl derivatives represented by Formula 1, energy transfer to dopant may easily occur because of a broad band gap between the highest occupied molecular orbital (HOMO) and the lowest unoccupied molecular orbital (LUMO) due to the introduction of a substituted or non-substituted amino group to its meta position. Further, the biphenyl derivatives e represented by Formula 1 has morphological stability because the compound represented by Formula 1 has a bulky aromatic amine pendent to the 4-substituted biphenyl backbone to prevent the crystallization of the molecule, can be easily processed due to its excellent thermal stability and its suitability for spin coating, and has a good electric charge transporting ability so that, when a metal complex is used as a dopant, the biphenyl derivatives exhibit excellent efficiency as a host for phosphorescent organic EL devices.

The biphenyl derivatives represented by Formula 1 can be used to form an emission layer and a hole injection layer.

In Formula 1, —N(Ar₁)(Ar₂), —N(Ar₃)(Ar₄), —N(Ar₅)(Ar₆), and —N(Ar₇)(Ar₈) are each independently a group represented by Formula 2, preferably, a carbazole derivative group represented by Formula 3.

Formula 2 is as follows:

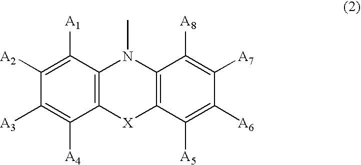

wherein X is —(CH₂)ₙ— wherein n is an integer between 0 and 2, —C(R₅)(R₆)—, —CH═CH—, —S—, —O—, or —Si(R₅)(R₆)—, and

A₁, A₂, A₃, A₄, A₅, A₆, A₇, A₈, R₅, and R₆ are each independently H; deuterium; a cyano group; a nitro group; a substituted or non-substituted linear or branched C₁-C₂₀ alkyl group; a substituted or non-substituted C₃-C₂₀ cycloalkyl group; a substituted or non-substituted C₄-C₃₀ aryl group; a substituted or non-substituted C₄-C₃₀ heteroaryl group; or a C₄-C₃₀ aryl group having at least one substituent selected from a C₁-C₂₀ alkyl halide group, —Si(R)(R′)(R″), a substituted or non-substituted C₁-C₂₀ alkyl group, a substituted or non-substituted C₁-C₂₀ alkoxy group, a substituted or non-substituted C₄-C₃₀ aryl group, a substituted or non-substituted C₄-C₃₀ heteroaryl group, and —N(R)(R′), wherein A₁ can be connected to A₂, A₂ can be connected to A₃, A₃ can be connected to A₄, A₅ can be connected to A₆, A₆ can be connected to A₇, and A₇ can be connected to A₈; and
R, R′, and R″ are each independently H, a substituted or non-substituted C₁-C₂₀ alkyl group, a substituted or non-substituted C₁-C₂₀ alkoxy group, a substituted or non-substituted C₄-C₃₀ aryl group, or a substituted or non-substituted C₄-C₃₀ heteroaryl group.

The group represented by Formula 2 may be a group selected from groups represented by Formulae 2a through 2 h:

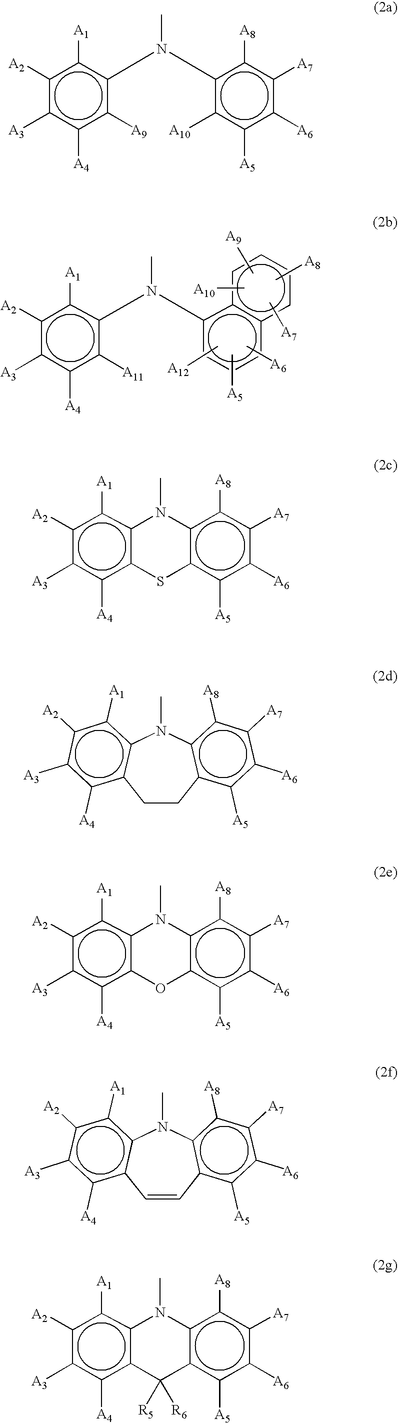

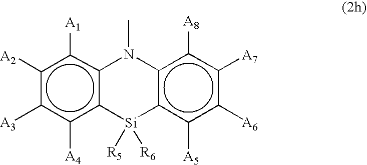

where A₁, A₂, A₃, A₄, A₅, A₆, A₇, A₈, A₉, A₁₀, A₁₁, A₁₂, R₅, and R₆ are each independently H; deuterium; a cyano group; a nitro group; a substituted or non-substituted linear or branched C₁-C₂₀ alkyl group; a substituted or non-substituted C₃-C₂₀ cycloalkyl group; a substituted or non-substituted C₁-C₁₀ alkenyl group; a substituted or non-substituted alkynyl group; a substituted or non-substituted C₄-C₃₀ aryl group; a substituted or non-substituted C₄-C₃₀ heteroaryl group; or a C₄-C₃₀ aryl group having at least one substituent selected from the group 9 consisting of a C₁-C₂₀ alkyl halide group, —Si(R)(R′)(R″), a substituted or non-substituted C₁-C₂₀ alkyl group, a substituted or non-substituted C₁-C₂₀ alkoxy group, a substituted or non-substituted C₄-C₃₀ aryl group, a substituted or non-substituted C₄-C₃₀ heteroaryl group, and —N(R)(R′), wherein A₁ can be connected to A₂, A₂ can be connected to A₃, A₃ can be connected to A₄, A₅ can be connected to A₆, A₆ can be connected to A₇, and A₇ can be connected to A₈; and

R, R′, and R″ are each independently H, a substituted or non-substituted C₁-C₂₀ alkyl group, a substituted or non-substituted C₁-C₂₀ alkoxy group, a substituted or non-substituted C₄-C₃₀ aryl group, or a substituted or non-substituted C₄-C₃₀ heteroaryl group.

Alternatively, in Formula 1, —N(Ar₁)(Ar₂), —N(Ar₃)(Ar₄), —N(Ar₅)(Ar₆), and —N(Ar₇)(Ar₈) are preferably each independently a group represented by a carbazole derivative group represented by Formula 3:

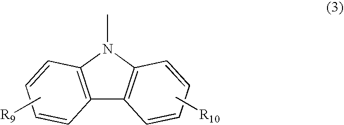

where R₉, and R₁₀ are each independently H; deuterium; a cyano group; a nitro group; a substituted or non-substituted linear or branched C₁-C₂₀ alkyl group; a substituted or non-substituted C₃-C₂₀ cycloalkyl group; a substituted or non-substituted C₄-C₃₀ aryl group; a substituted or non-substituted C₄-C₃₀ heteroaryl group; or a C₄-C₃₀ aryl group having at least one substituent selected from a C₁-C₂₀ alkyl halide group, —Si(R)(R′)(R″), a substituted or non-substituted C₁-C₂₀ alkyl group, a substituted or non-substituted C₁-C₂₀ alkoxy group, a substituted or non-substituted C₄-C₃₀ aryl group, a substituted or non-substituted C₄-C₃₀ heteroaryl group, and —N(R)(R′), wherein R, R′, and R″ are each independently H, a substituted or non-substituted C₁-C₂₀ alkyl group, a substituted or non-substituted C₁-C₂₀ alkoxy group, a substituted or non-substituted C₄-C₃₀ aryl group, or a substituted or non-substituted C₄-C₃₀ heteroaryl group.

In Formula 3, R₉ and R₁₀ may be preferably represented by Formula 4:

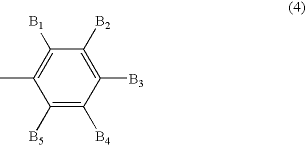

where B₁, B₂, B₃, B₄, and B₅ are each independently H; deuterium; a cyano group; a nitro group; a substituted or non-substituted linear or branched C₁-C₂₀ alkyl group; a substituted or non-substituted C₃-C₂₀ cycloalkyl group; a substituted or non-substituted C₄-C₃₀ aryl group; a substituted or non-substituted C₄-C₃₀ heteroaryl group; or a C₄-C₃₀ aryl group having at least one substituent selected from a C₁-C₂₀ alkyl halide group, —Si(R)(R′)(R″), a substituted or non-substituted C₁-C₂₀ alkyl group, a substituted or non-substituted C₁-C₂₀ alkoxy group, a substituted or non-substituted C₄-C₃₀ aryl group, a substituted or non-substituted C₄-C₃₀ heteroaryl group, and —N(R)(R′), wherein R, R′, and R″ are each independently H, a substituted or non-substituted C₁-C₂₀ alkyl group, a substituted or non-substituted C₁-C₂₀ alkoxy group, a substituted or non-substituted C₄-C₃₀ aryl group, or a substituted or non-substituted C₄-C₃₀ heteroaryl group.

According another embodiment of the present invention, —R₁N(Ar₁)(Ar₂), —R₂N(Ar₃)(Ar₄), —R₃N(Ar₅)(Ar₆), and —R₄N(Ar₇)(Ar₈) of Formula 1 may be each independently a group represented by Formula 5, preferably, Formula 6.

Formula 5 is as follows:

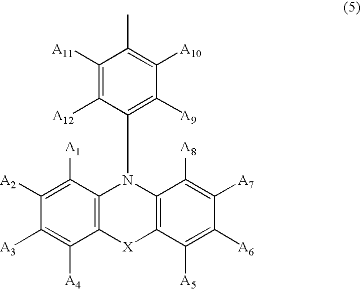

where X is —(CH₂)ₙ— where n is an integer between 0 and 2, —C(R₅)(R₆)—, —CH═CH—, —S—, —O—, or —Si(R₅)(R₆)—, and

A₁, A₂, A₃, A₄, A₅, A₆, A₇, A₈, A₉, A₁₀, A₁₁, A₁₂, R₅, and R₆ are each independently H; deuterium; a cyano group; a nitro group; a substituted or non-substituted linear or branched C₁-C₂₀ alkyl group; a substituted or non-substituted C₃-C₂₀ cycloalkyl group; a substituted or non-substituted C₄-C₃₀ aryl group; a substituted or non-substituted C₄-C₃₀ heteroaryl group; or a C₄-C₃₀ aryl group having at least one substituent selected from a C₁-C₂₀ alkyl halide group, —Si(R)(R′)(R″), a substituted or non-substituted C₁-C₂₀ alkyl group, a substituted or non-substituted C₁-C₂₀ alkoxy group, a substituted or non-substituted C₄-C₃₀ aryl group, a substituted or non-substituted C₄-C₃₀ heteroaryl group, and —N(R)(R′), wherein A₁ can be connected to A₂, A₂ can be connected to A₃, A₃ can be connected to A₄, A₅ can be connected to A₆, A₆ can be connected to A₇, A₇ can be connected to A₈, A can be connected to A₁₀, and A₁₁ can be connected to A₁₂; and

R, R′, and R″ are each independently H, a substituted or non-substituted C₁-C₂₀ alkyl group, a substituted or non-substituted C₁-C₂₀ alkoxy group, a substituted or non-substituted C₄-C₃₀ aryl group, or a substituted or non-substituted C₄-C₃₀ heteroaryl group.

The group represented by Formula 5 may be a group selected from groups represented by Formulae 3a through 3 h:

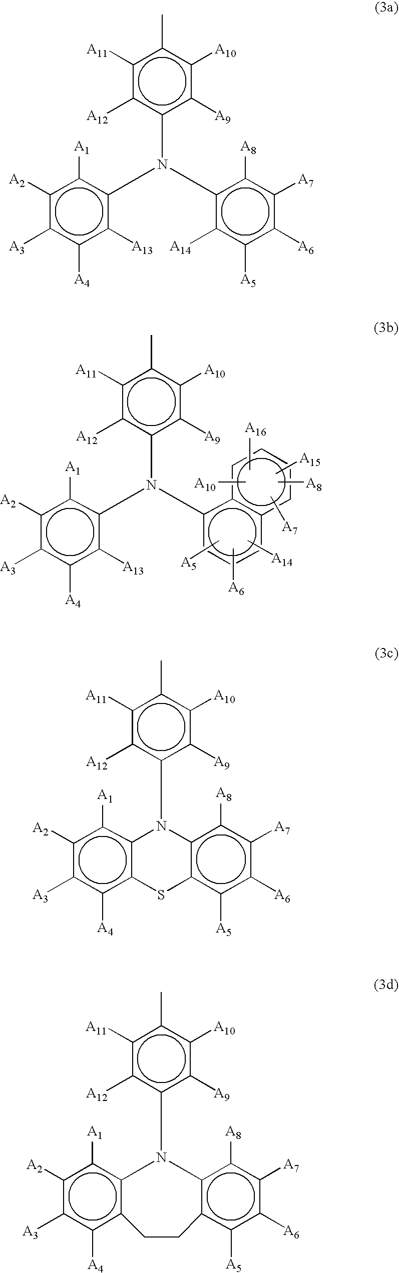

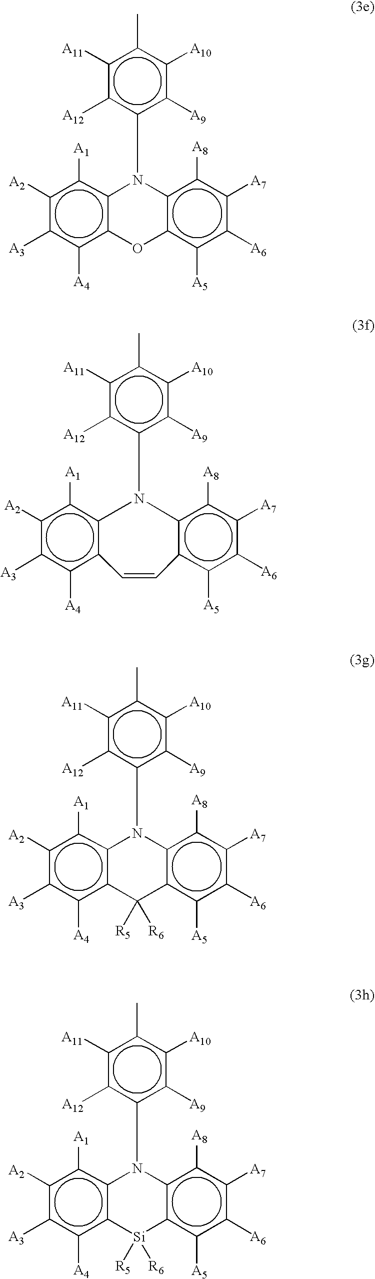

where A₁, A₂, A₃, A₄, A₅, A₆, A₇, A₈, A₉, A₁₀, A₁₁, A₁₂, A₁₃, A₁₄, A₁₅, A₁₆, R₅, and R₆ are each independently H; deuterium; a cyano group; a nitro group; a substituted or non-substituted linear or branched C₁-C₂₀ alkyl group; a substituted or non-substituted C₃-C₂₀ cycloalkyl group; a substituted or non-substituted C₄-C₃₀ aryl group; a substituted or non-substituted C₄-C₃₀ heteroaryl group; or a C₄-C₃₀ aryl group having at least one substituent selected from the group consisting of a C₁-C₂₀ alkyl halide group, —Si(R)(R′)(R″), a substituted or non-substituted C₁-C₂₀ alkyl group, a substituted or non-substituted C₁-C₂₀ alkoxy group, a substituted or non-substituted C₄-C₃₀ aryl group, a substituted or non-substituted C₄-C₃₀ heteroaryl group, and —N(R)(R′), wherein A₁ can be connected to A₂, A₂ can be connected to A₃, A₃ can be connected to A₄, A₅ can be connected to A₆, A₆ can be connected to A₇, A₇ can be connected to A₈, A₉ can be connected to A₁₀, and A₁₁ can be connected to A₁₂; and

R, R′, and R″ are each independently H, a substituted or non-substituted C₁-C₂₀ alkyl group, a substituted or non-substituted C₁-C₂₀ alkoxy group, a substituted or non-substituted C₄-C₃₀ aryl group, or a substituted or non-substituted C₄-C₃₀ heteroaryl group.

According still another embodiment of the present invention, —R₁N(Ar₁)(Ar₂), —R₂N(Ar₃)(Ar₄), —R₃N(Ar₅)(Ar₆), and —R₄N(Ar₇)(Ar₈) of Formula 1 may be each independently a group represented by Formula 6:

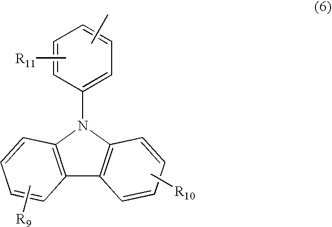

R₉, R₁₀ and R₁₁ are each independently H; deuterium; a cyano group; a nitro group; a substituted or non-substituted linear or branched C₁-C₂₀ alkyl group; a substituted or non-substituted C₃-C₂₀ cycloalkyl group; a substituted or non-substituted C₄-C₃₀ aryl group; a substituted or non-substituted C₄-C₃₀ heteroaryl group; or a C₄-C₃₀ aryl group having at least one substituent selected from a C₁-C₂₀ alkyl halide group, —Si(R)(R′)(R″), a substituted or non-substituted C₁-C₂₀ alkyl group, a substituted or non-substituted C₁-C₂₀ alkoxy group, a substituted or non-substituted C₄-C₃₀ aryl group, a substituted or non-substituted C₄-C₃₀ heteroaryl group, and —N(R)(R′), wherein R, R′, and R″ are each independently H, a substituted or non-substituted C₁-C₂₀ alkyl group, a substituted or non-substituted C₁-C₂₀ alkoxy group, a substituted or non-substituted C₄-C₃₀ aryl group, or a substituted or non-substituted C₄-C₃₀ heteroaryl group.

In Formula 6, R₉, R₁₀, and R₁₁ may be preferably represented by Formula 4:

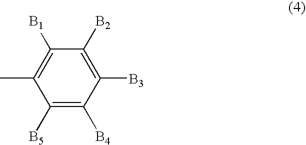

where B₁, B₂, B₃, B₄, and B₅ are described as above.

The biphenyl derivative represented by Formula 1 may be represented by one of Formulae A through D:

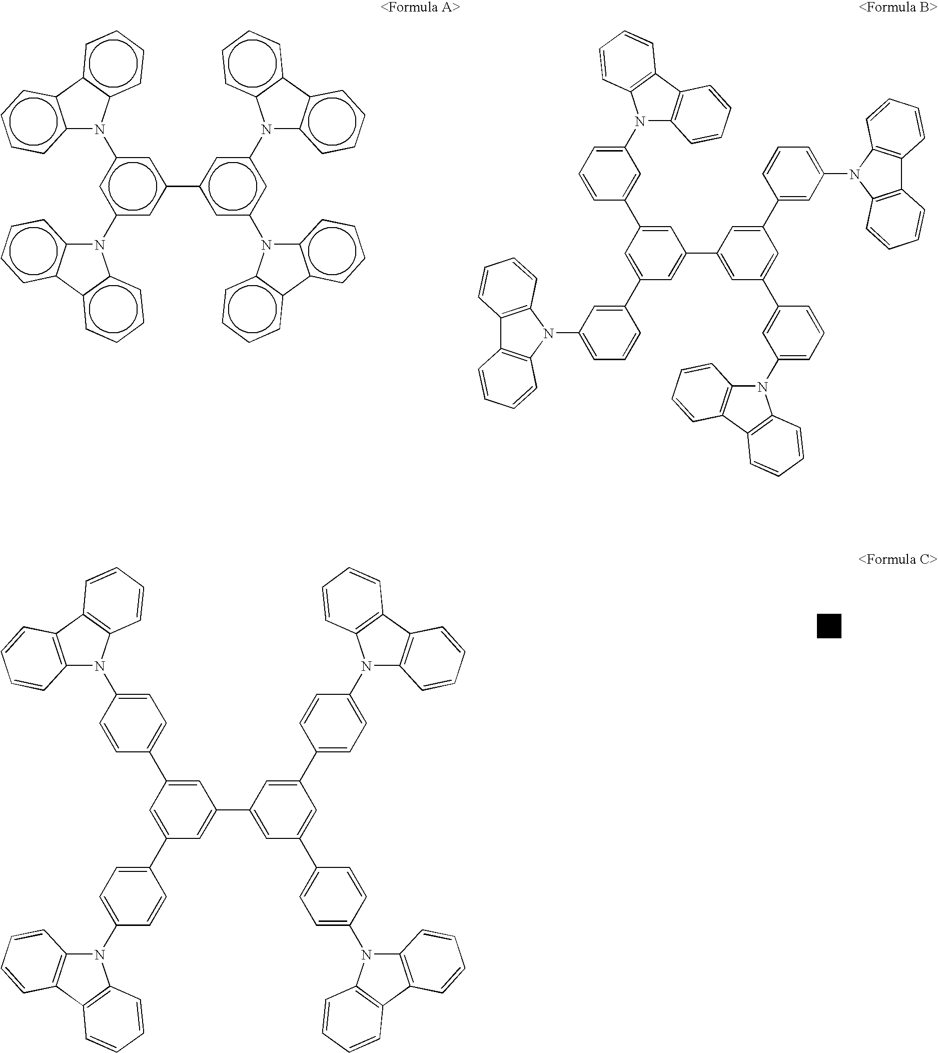

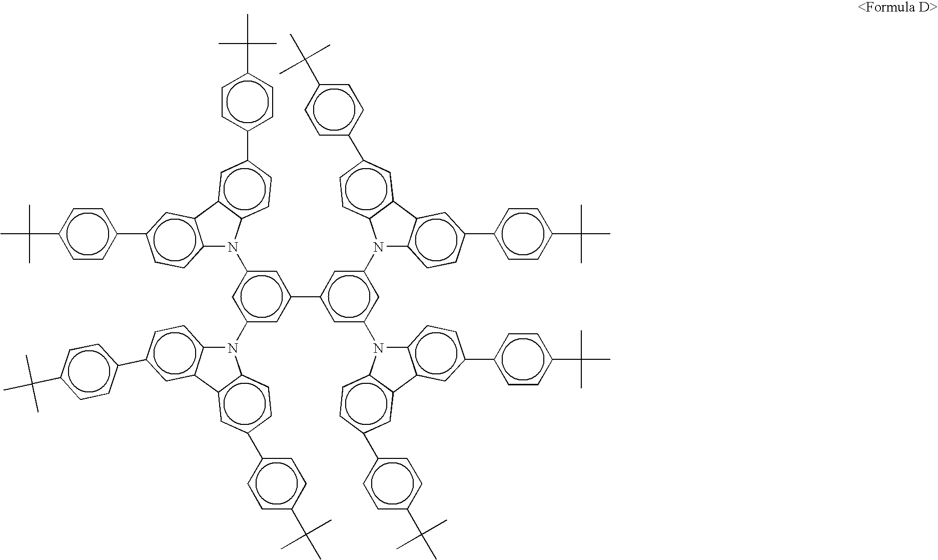

The host material of the emission layer according to an embodiment of the present invention has a structure in which 4 bulky amine groups are substituted at 3,5,3′, and 5′ positions of biphenyl. Accordingly, crystallization of the molecule can be prevented. That is, the emission layer has an amorphous structure that retains morphological stability.

In addition, the host material has better thermal stability than commonly used CBP (4,4′-N,N′-dicarbazole-biphenyl) or m-CP (1,3-di(9H-carbazol-9-yl)benzene), can be easily purified, and can be used in a solution process to manufacture an organic EL device. In general, a matrix polymer, such as polystyrene, is required to perform the solution process, such as spin coating and inkjet printing. However, the host material according to an embodiment of the present invention produces the same effects without the matrix polymer.

An organic EL device according to an embodiment of the present invention may include an organic layer composed of the biphenyl derivative interposed between a pair of electrodes.

The organic layer may be an emission layer (EML) or a hole injection layer (HIL), preferably, the emission layer. The composition of the emission layer may be 70-99.9 wt % of the biphenyl derivative and 0.1 to 30 wt % of a dopant.

An organic EL device using the biphenyl derivative represented by Formula 1, and a method of manufacturing the same will now be described.

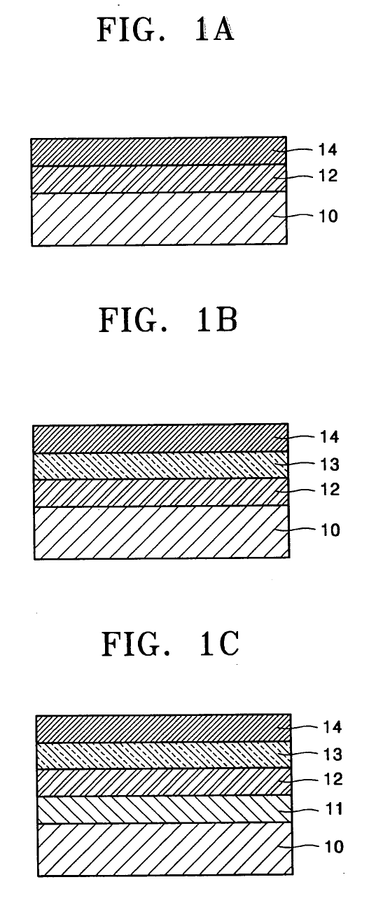

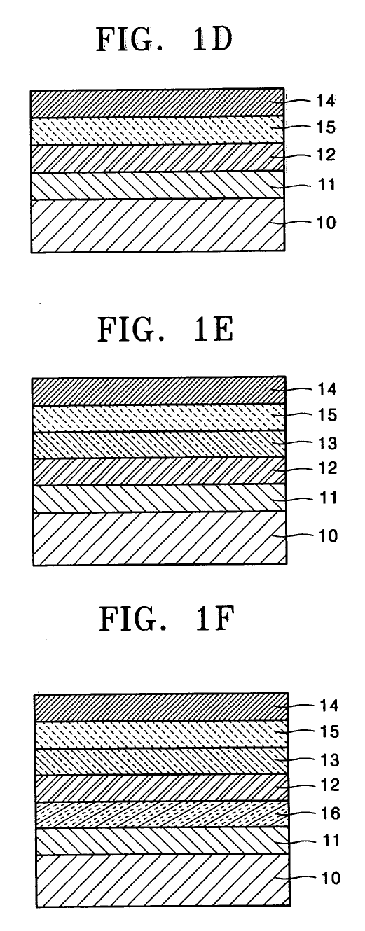

FIGS. 1A through 1F are sectional views of organic EL devices according to embodiments of the present invention.

Referring to FIG. 1A, an emission layer 12 which is composed of the biphenyl derivative represented by Formula 1 is interposed between a first electrode 10 and a second electrode 14.

Referring to FIG. 1B, the structure of the organic EL device illustrated in FIG. 1B is the same as the structure of the organic EL device illustrated in FIG. 1A, except that a hole blocking layer (HBL) 13 is interposed between the emission layer 12 and the second electrode 14.

Referring to FIG. 1C, the structure of the organic EL device illustrated in FIG. 1C is the same as the structure of the organic EL device illustrated in FIG. 1B, except that a hole injection layer 11 is interposed between the first electrode 10 and the emission layer 12.

Referring to FIG. 1D, the structure of the organic EL device illustrated in FIG. 1D is the same as the structure of the organic EL device illustrated in FIG. 1C, except that the hole blocking layer 13 is replaced with an electron transport layer 15.

Referring to FIG. 1E, the structure of the organic EL device illustrated in FIG. 1E is the same as the structure of the organic EL device illustrated in FIG. 1C, except that the electron transport layer (ETL) 15 is formed between the hole blocking layer 13 and the second electrode 14. In some cases, an electron injection layer (not shown) may further interposed between the electron transport layer 15 and the second electrode 14 of the organic EL device illustrated in FIG. 1E.

Referring to FIG. 1F, the structure of the organic EL device illustrated in FIG. 1F is the same as the structure of the organic EL device illustrated in FIG. 1E, except that a hole transport layer (HTL) 16 is interposed between the hole injection layer 11 and the emission layer 12. The hole transport layer may prevent the penetration of impurities to the emission layer 12 from the hole injection layer 11.

Organic EL devices having the above structures can be manufactured using conventional methods.

A method of manufacturing an organic EL device according to an embodiment of the present invention will now be described in detail with reference to FIGS. 1A through 1F.

First, an anode forming material is coated on a substrate, thus forming a first electrode that is an anode. The substrate may be a substrate used in a conventional organic electroluminescent device, such as a glass substrate which is transparent and water proof, has a smooth surface, and can be easily treated, or a transparent plastic substrate. The anode forming material may be a transparent and highly conductive metal, such as Indium Tin Oxide (ITO), Indium Zinc Oxide (IZO), SnO₂, ZnO, or the like.

A hole injection layer forming material may be thermally evaporated in a high vacuum condition to form the hole injection layer. The hole injection layer forming material can be dissolved in a solution, and then the resulting solution can be deposited by spin coating, dip-coating, doctor blading, inkjet printing, thermal transferring, or organic vapor phase deposition (OVPD) to form the hole injection layer. The formation of the hole injection layer is optional. The hole injection layer may have a thickness of 50 to 1500 Å. When the thickness of the hole injection layer is less than 50 Å, a hole injecting ability deteriorates. When the thickness of the hole injection layer is greater than 1500 Å, a driving voltage of the device increases.

The HIL forming material may be, but is not limited to, copper phthalocyanine (CuPc), a starburst-type amine such as 4,4′,4″-tri(N-carbazolyl)triphenylamine (TCTA), 4,4′,4″-tris(3-methylphenyl-phenylamino)triphenylamine (m-MTDATA), IDE406 (available from Idemitsu Kosan Co., Ltd.), or the like.

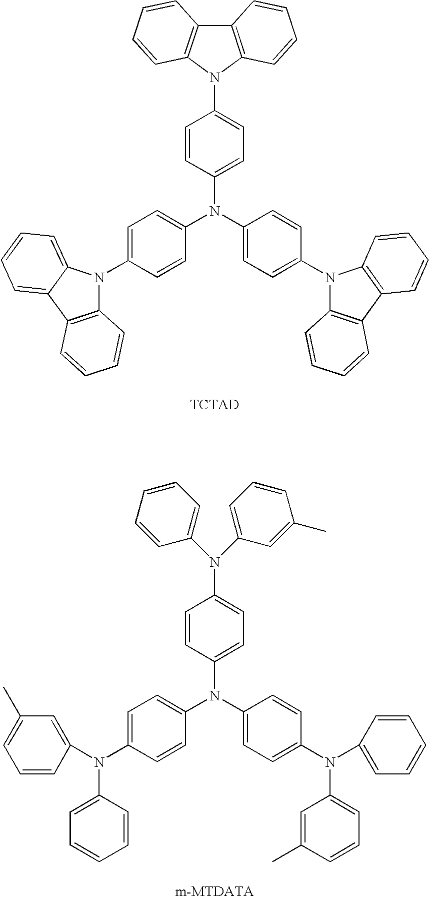

A hole transport layer forming material may be deposited on the hole injection layer using above-described various methods, thus forming the hole transport layer. The formation of the hole transport layer is optional. The HTL forming material may be, but is not limited to, N,N′-bis(3-methylphenyl)-N,N′-diphenyl-[1,1-biphenyl]-4,4′-diamine (TPD); N,N′-diphenyl-N,N′-bis(1-naphthyl)-(1,1′-biphenyl)-4,4′diamine (NMP); N,N′-di(naphtalene-1-yl)-N,N′-diphenyl-benzidine (α-NPD); IDE320 (obtained from Idemitsu Kosan Co., Ltd.), or the like. The thickness of the hole transport layer may be in the range of about 50 to about 1500 Å. When the thickness of the hole transport layer is less than 50 Å, a hole transporting ability deteriorate. When the thickness of the hole transport layer is greater than 1500 Å, the driving voltage of the device increases.

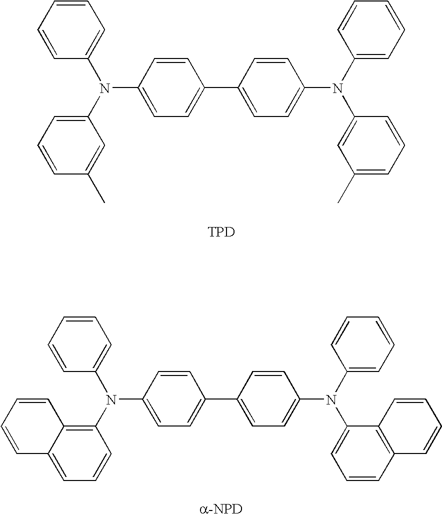

The emission layer is formed on the hole transport layer using the phosphorescent dopant and the phosphorescent host. The method of forming the emission layer may be, but is not limited to, spin coating, inkjet printing, laser transferring or the like.

The thickness of the emission layer may be in the range of about 100 to about 800 Å. When the thickness of the emission layer is less than 100 Å, the efficiency and lifetime of the device decrease. When the thickness of the emission layer is greater than 800 Å, the driving voltage of the device increases.

A hole blocking layer forming material may be vacuum deposited or spin coated on the emission layer, thus forming the hole blocking layer. The formation of the hole blocking layer is optional. The HBL forming material may be a material which transports electrons and has a higher ionization potential than the emission compound. Examples of the HBL forming material may include aluminum(III) bis(2-methyl-8-quinolinato)₄-phenylpheolate (BAlq), 2,9-dimethyl-4,7-diphenyl-1,10-phenanthroline (BCP), 2,2′,2″-(1,3,5-benzenetriyl)tris-(1-phenyl-1H-benzimidazole) (TPBI), and the like. However, the HBL forming material is not limited thereto.

The thickness of the hole blocking layer may be in the range of about 30 to about 500 Å. When the thickness of the hole blocking layer is less than 30 Å, holes cannot be effectively blocked, thus decreasing the efficiency of the device. When the thickness of the hole blocking layer is greater than 500 Å, the driving voltage of the device increases.

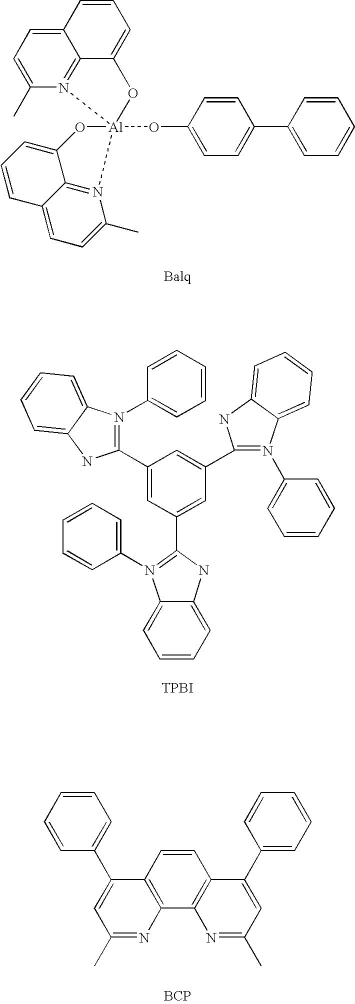

An electron transport layer forming material is vacuum deposited or spin coated on the hole blocking layer, thus forming the electron transport layer. The ETL forming material may be, but is not limited to, aluminum(III) tris(8-hydroxyquinolate) (Alq₃). The thickness of the electron transport layer may be in the range of about 50 Å to about 600 Å. When the thickness of the electron transport layer is less than 50 Å, the lifetime of the device decreases. When the thickness of the electron transport layer is greater than 600 Å, the driving voltage of the device increases.

The electron injection layer may be optionally formed on the electron transport layer. The electron injection layer may be composed of LiF, NaCl, CsF, Li₂O, BaO, Liq, or the like. The thickness of the electron injection layer may be in the range of about 1 to about 100 Å. When the thickness of the electron injection layer is less than 1 Å, an electron injecting ability decreases, thus increasing the driving voltage of the device. When the thickness of the electron injection layer is greater than 100 Å, the electron injection layer acts as an insulator, thus increasing the driving voltage of the device.

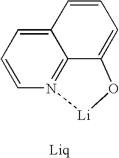

Then, a cathode forming metal is vacuum thermally deposited on the EIL, thus forming a second electrode that acts as a cathode. As a result, the organic EL device is completely manufactured.

The cathode metal may be Li, Mg, Al, Al—Li, Ca, Mg—In, Mg—Ag, or the like.

The organic EL device according to the present invention includes an anode, an HIL, an HTL, an EML, a HBL, an ETL, an EIL, a cathode, and when needed, one or two intermediate layers. In addition, to aforementioned layers, the organic EL device may further include an EBL.

The present invention will be described in further detail with reference to the following examples. These examples are for illustrative purposes only and are not intended to limit the scope of the present invention.

### EXAMPLES

### Synthesis Example 1

### Manufacture of Compound A

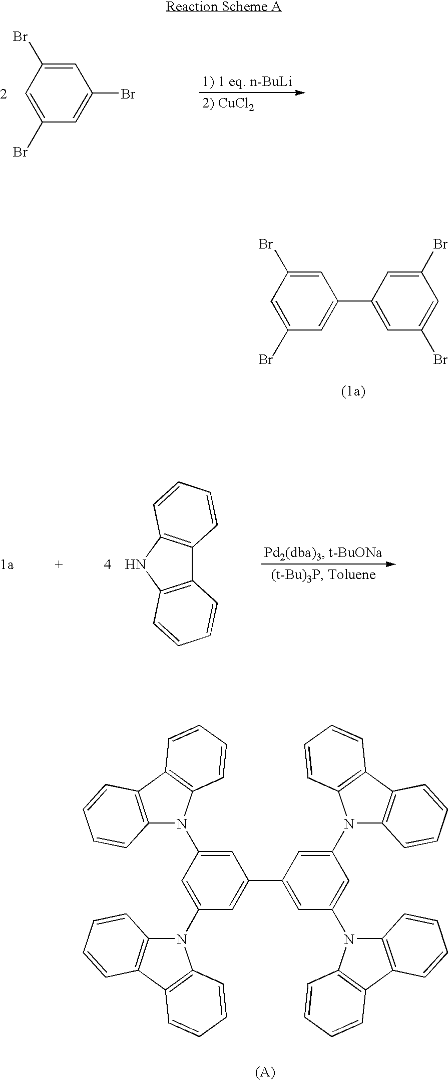

1) Manufacture of Compound 1a

15.74 g (1.0 eq) of 1,3,5-tribromobenzene was dissolved in 100 ml of an anhydrous THF and then cooled to −78° C. 34.4 ml (1.1 eq) of 1.6 M n-butyllithium (n-BuLi) was slowly added thereto, and the result was mixed for one hour. 7.395 g (1.1 eq) of CuCl₂ was quickly added to the resulting mixture, and then the result was reacted for 12 hours. After the reaction was completed, the reaction mixture was extracted using water and ethylacetate separately three times each, dried over anhydrous MgSO₄ and concentrated, and then re-crystallized using CH₂Cl₂/acetone, thus producing the compound 1a (Yield: 90%).

2) Manufacture of Compound A

2.5 g (5.3 mmole) of the compound 1a and 3.6 g (4.04 eq) of carbazole were dissolved in 60 ml of an anhydrous toluene, and 4.13 g (8.08 eq) of sodium tert-butoxide (t-BuONa), 0.323 g (0.3 eq) of tri(tert-butyl)phosphine {(t-Bu)₃P}, and 1.169 g (0.24 eq) of Pd₂(dba)₃ (wherein dba is dibenzylideneacetone) as a catalyst were added to the resulting solution and reacted at 120° C. for 48 hours.

After the reaction was completed, the reaction mixture was extracted using water and ethylacetate, dried, and purified using an open column using n-hexane and ethylacetate as an elute to remove side reaction products, thus producing the compound represented by Formula A. The structure of Formula A was identified using ¹H-NMR and an atomic analysis:

¹H-NMR (CDCl₃, δ) 7.10-8.7 (m, 38H, Aromatic Protons),

theoretical values of atomic analysis of C₆₀H₃₈N₄: C, 88.43; H, 4.70; N, 6.87, 2 and measured values of atomic analysis of C₆₀H₃₈N₄: C, 88.45; H, 4.72; N, 6.85.

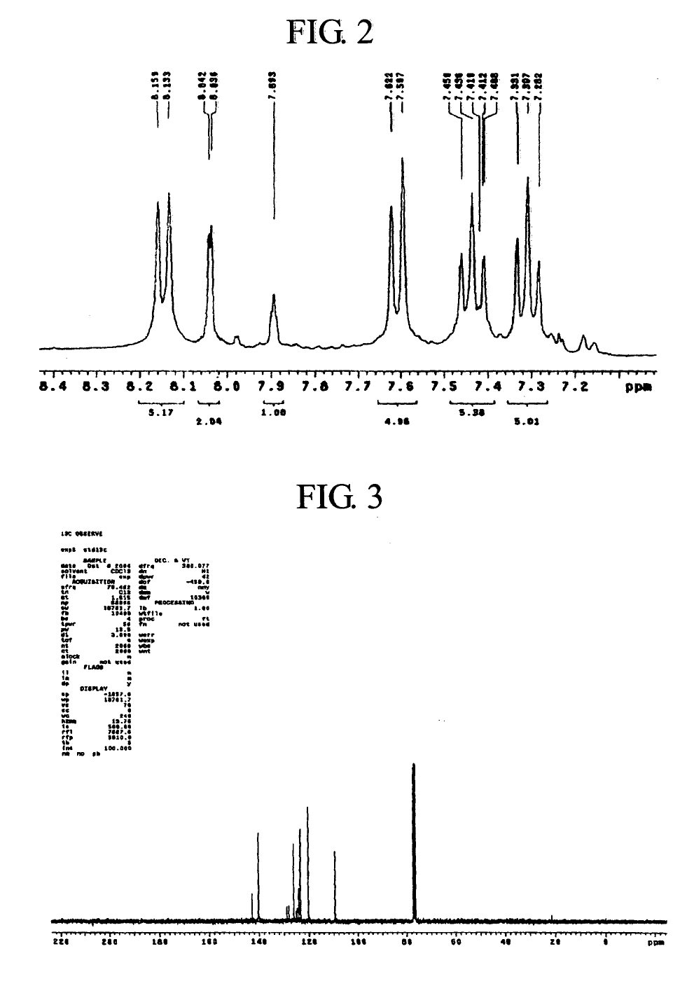

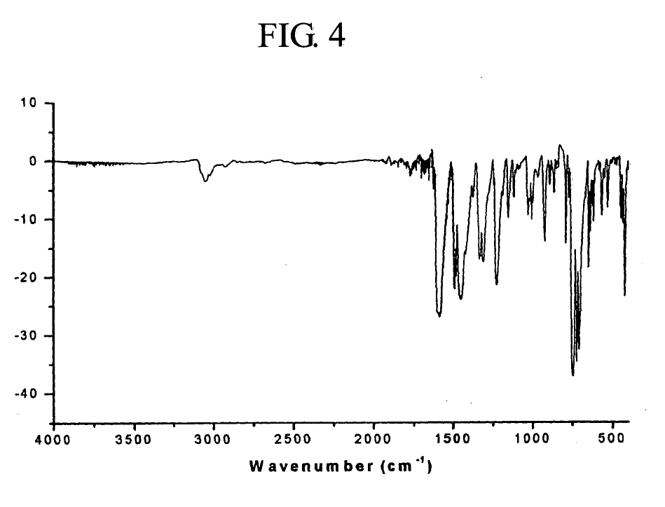

FIG. 2 illustrates a ¹H NMR spectrum of TCBP represented by Formula A according to an embodiment of the present invention. FIG. 3 illustrates a ¹³C NMR spectrum of TCBP represented by Formula A according to an embodiment of the present invention. FIG. 4 illustrates a FT-IR spectrum (on KBr) of TCBP represented by Formula A according to an embodiment of the present invention.

### Synthesis Example 2

### Manufacture of Compound Represented by Formula B

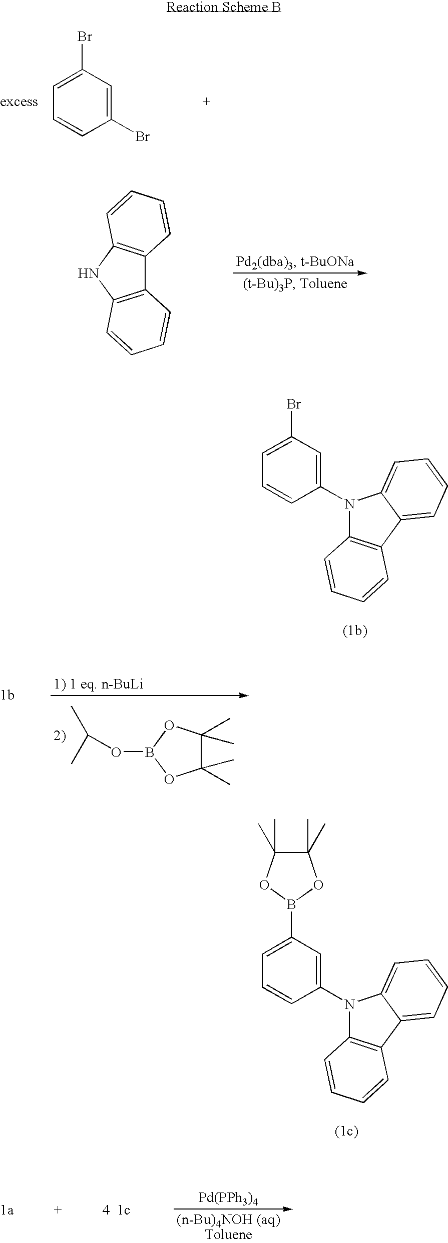

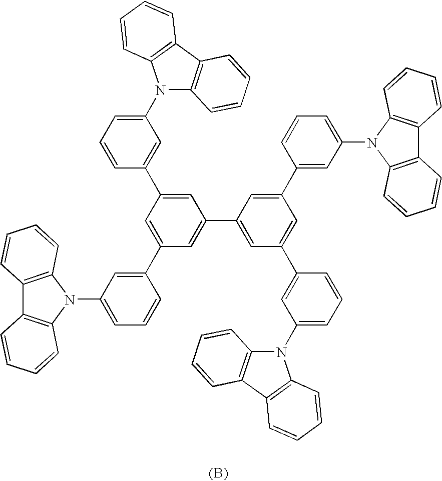

Manufacture of Compound 1b

20.87 g (0.168 mole, 4 eq) of 1,3-dibromobenzene and 7 g (1 eq) of carbazole were dissolved in 70 ml of anhydrous toluene, and 12.1 g (3 eq) of sodium tert-butoxide, 0.424 g (0.05 eq) of tri(tert-butyl)phosphine, and 1.533 g (0.04 eq) of Pd₂(dba)₃ as a catalyst were added to the resulting solution and reacted at 120° C. for 36 hours. After the reaction was completed, the reaction mixture was extracted using water and ethylacetate, dried, and purified using an open column using n-hexane and ethylacetate as an elute to remove side reaction products, thus producing the compound 1b (Yield: 50%).

2) Manufacture of Compound 1c

1.7 g (5.3 mmol) of the compound 1b was dissolved in 30 ml of anhydrous THF, and then cooled to −78° C. 3.463 mL (1.05 eq) of 1.6 M n-butyllithium was slowly added to the cooled solution and the result was stirred for 1 hour. 1.031 g (1.05 eq) of 2-isopropoxy-4,4,5,5-tetramethyl-1,3,2-dioxaborolan was added to the mixture and the result was reacted for 1 hour. After the reaction was completed, the reaction mixture was extracted using water and acetate separately two times each, dried over anhydrous MgSO₄, and purified using open column using n-hexane and ethylacetate as an elute to remove side reaction products, thus producing the compound 1c. The structure of a compound 1c was confirmed using ¹H-NMR.

3) Manufacture of Compound Represented by Formula B

0.5 g (1.1 mmole) of the compound 1a and 1.572 g (4.0 eq) of the compound 1c were dissolved in 60 ml of a hydrous toluene. Then, 6.27 ml (2 eq) of Et4NOH (20 wt % aqueous solution), and 0.197 g (0.04 eq) of Pd(PPh₃)₄ as a catalyst were added thereto and the result was reacted at 120° C. for 48 hours. After the reaction was completed, the reaction mixture was extracted using water and chloroform, dried, and purified using an open column using n-hexane and ethylacetate as an elute to remove side reaction products, thus producing a compound B. The structure of the compound B was confirmed using ¹H-NMR and atomic analysis:

¹H-NMR (CDCl₃, δ) 7.10-8.8 (m, 54H, Aromatic Protons),

theoretical values of atomic analysis of C₈₄H₅₄N₄: C, 90.13; H, 4.86; N, 5.01, and measured values of atomic analysis of C₈₄H₅₄N₄: C, 90.11; H, 4.88; N, 4.99.

### Synthesis Example 3

### Manufacture of Compound Represented by Formula C

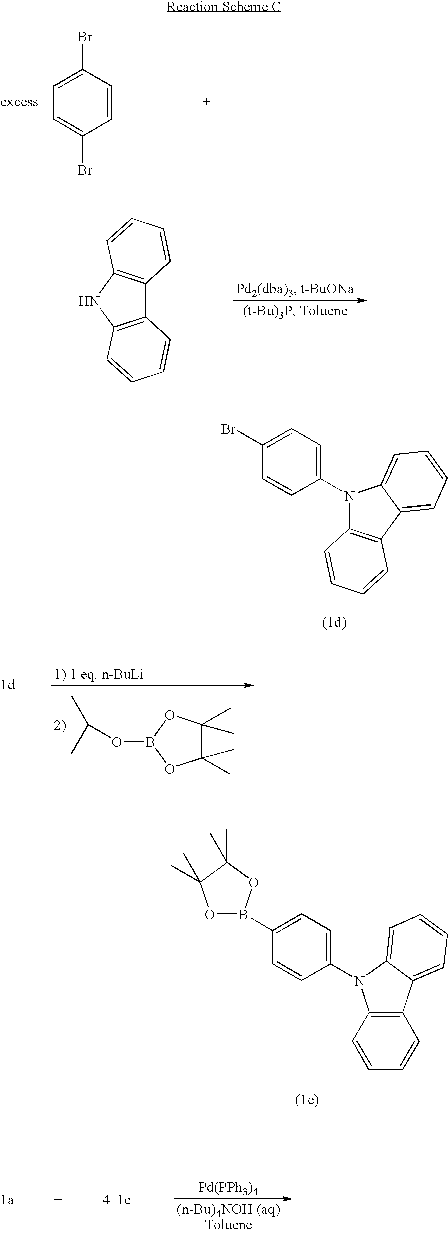

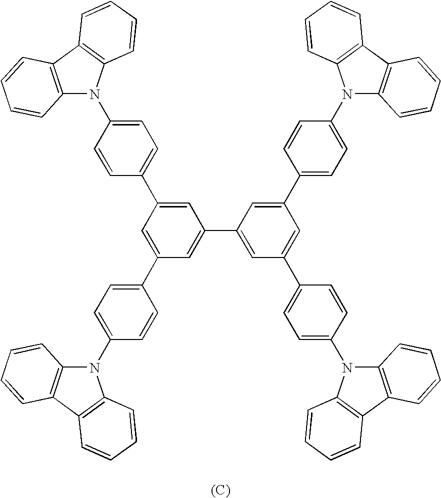

A compound C was produced in the same manner as the compound B, except that 1,4-dibromobenzen was used as the starting material instead of 1,3-dibromobenzene. The structure of the compound C was identified using ¹H-NMR.

### Synthesis Example 4

### Manufacture of Compound D

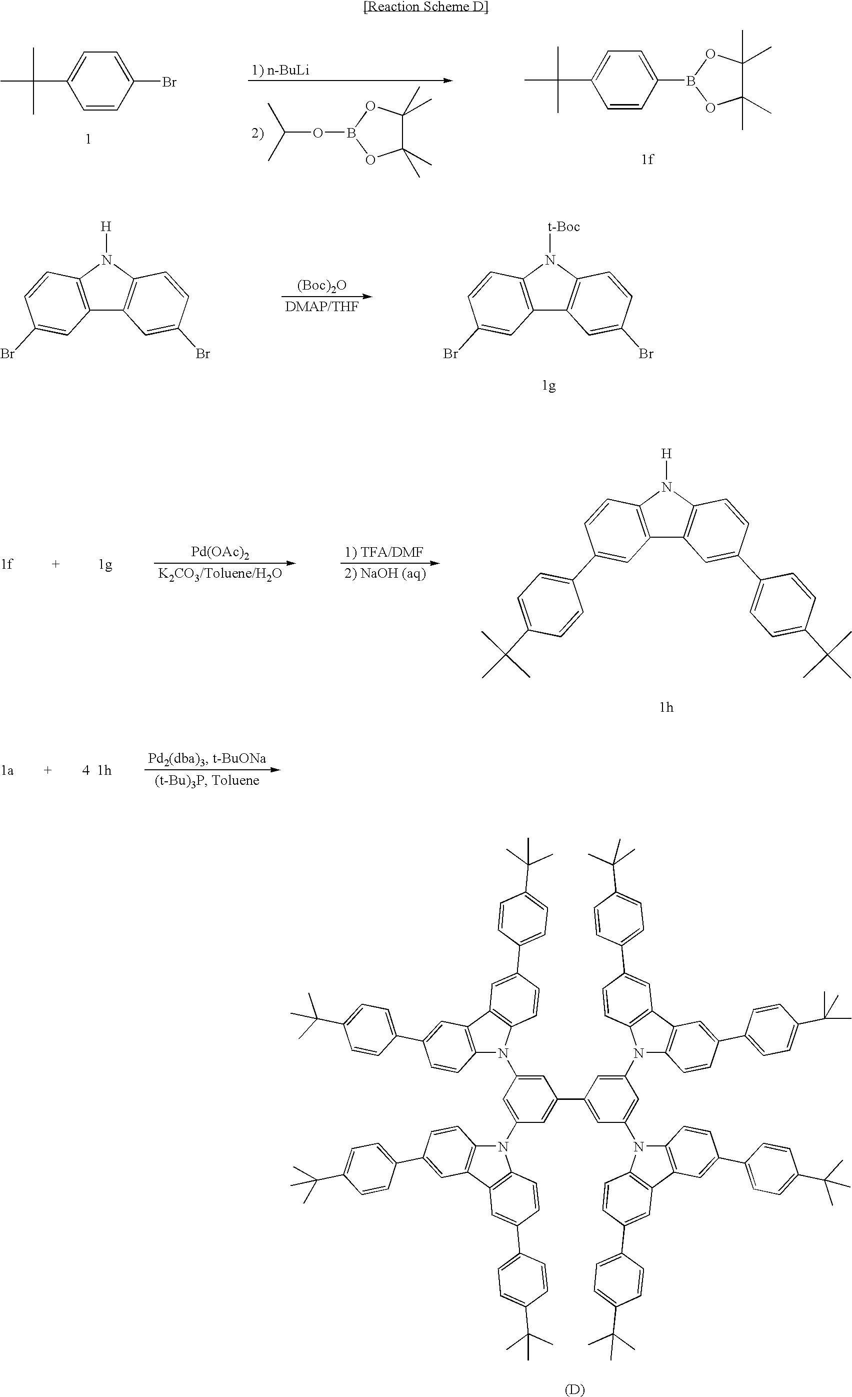

1) Manufacture of Compound 1f

47.5 g (0.223 mol) of 1-bromo-4-tert-butylbenzene was dissolved in 500 ml of anhydrous THF and the result was cooled to −70° C. 127.4 ml (0.3185 mol) of 2.5 M n-butyllithium was slowly added to the reaction mixture and the result was stirred for about 30 minutes. 50 ml (0.245 mol) of 2-isopropoxy-4,4,5,5-tetramethyl-1,3,2-dioxaborolan was added thereto and the result was stirred for about 1 hour.

After the reaction was completed, 500 ml of distilled water was added to the reaction product, thus producing a white precipitate. The white precipitate was filtered, washed using 200 ml of distilled water, and dried under a reduced pressure, thus producing 43 g of the compound 1f. The structure of the compound 1f was identified using ¹H-NMR.

2) Manufacture of Compound 1g

70 g (0.22 mol) of 9-H-3,3-bromocarbazole was dissolved in 1 L of THF in a

1 L flask. 56.7 g (0.26 mol) of (Boc)₂O (where “Boc” is a tert-butoxycarbonyl group) and 3.2 g (0.026 mol) of DMAP(4-dimethylaminopyridine) were added to the reaction mixture and the result stirred at room temperature for about 12 hours.

After the reaction was completed, the result was concentrated under a reduced pressure, and 1 L of ethyl acetate and 1 L of water were added thereto, thus separating an organic layer. The separated organic layer was washed with 1 L of 1N HCl, 1 L of water, and 1 L of NaHCO₃ and dried under a reduced pressure to obtain 75 g of the solid, white compound 1g. The structure of the compound 1g was identified using ¹H-NMR.

3) Manufacture of Compound 1h

49 g (0.188 mol) of the compound 1f and 24 g (0.055 mol) of the compound 1g were added to 300 ml of toluene and 200 ml of distilled water, and 1.2 g (5.5 mol) of Pd(OAc)₂ and 53 g of K₂CO₃ were added thereto and the result was stirred at 70° C. for 16 hours.

After the reaction was completed, the reaction mixture was extracted using 400 ml of ethyl acetate and concentrated under a reduced pressure. 30 ml of trifluoroacetic acid (TFA) and 100 ml of DMF were added to the resulting residue and the result was stirred at 100° C. for about 48 hours. The result was concentrated under a reduce pressure to remove TFA, and 100 ml of 2N NaOH solution and 100 ml of water were added thereto, thus producing a solid, white precipitate. The resulting precipitate was filtered and washed using 100 ml of ethyl acetate to obtain 20 g of a compound 1h. The structure of the compound 1h was identified using ¹H-NMR.

¹H-NMR (DMSO-d₆, δ) 1.33 (m, 18H, 2-C(CH₃)₃), 3.91 (t, 4H, 2-OCH₂—), 7.20-8.75 (m, 14H, Aromatic Protons), 11.3 (s, 1H, —N—H of carbazole)

4) Manufacture of Compound D

0.902 g (6.3 eq) of sodium tert-butoxide, 0.03 g (0.1 eq) of tri(tert-butyl)phosphine, and 0.109 g (0.08 eq) of Pd₂(dba)₃ as a catalyst were added to the mixture of 0.7 g (1.5 mmole) of the compound 1a and 2.54 g (4.2 eq) of the compound 1h dissolved in 50 ml of anhydrous toluene and the result was reacted at 130° C. for 36 hours. After the reaction was completed, the reaction product was extracted using water and chloroform, dried, and purified using an open column using n-hexane and methylenechloride as an elute to remove side reaction products, thus producing the Compound D. The structure of the Compound D was identified using ¹H-NMR.

¹H-NMR(CDCl₃, δ) 1.34 (m, 72H, 8-C(CH₃)₃), 7.30-8.75 (m, 62H, Aromatic Protons).

In order to increase efficiency of an EL device, excitons that are excited

at a host must be effectively transferred to the metal complex. Accordingly, the band gap between the host material and the metal complex is an important factor to consider when a host material is selected. The phosphorescent host material can have a band gap that encompasses an energy range between HOMO and LUMO of the metal complex. In general, the more the PL spectrum of the host overlaps the UV-VIS spectrum of the metal complex, the higher the emission efficiency of the EL device that can be obtained. A phosphorescent material having these properties is a mixture of TCBP, which is used as the host material in embodiments of the present invention, and pq2Ir(acac) as a dopant.

Thermal properties of the compound represented by Formula A were measured using thermogravimetric analysis (TGA) and differential scanning calorimetry (DSC) under a nitrogen atmosphere at 10° C./min.

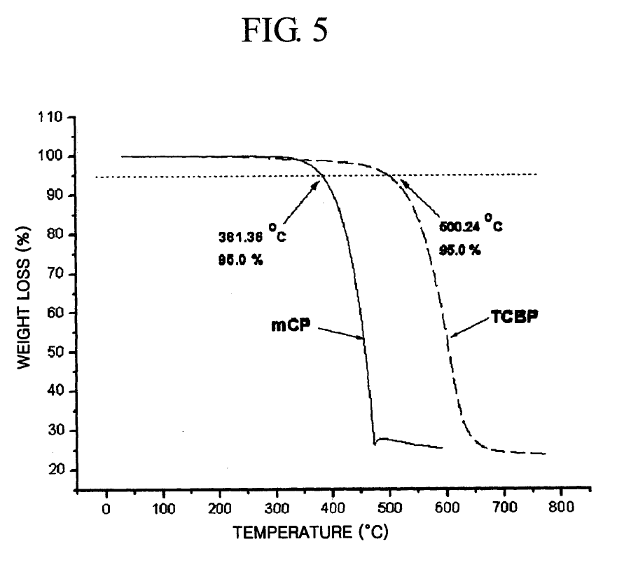

The results of TGA are illustrated in FIG. 5. The weight of a conventional phosphorescent host m-CP dramatically decreased at about 381° C., but the weight of the compound represented by Formula A dramatically decreased at about 500.24° C.

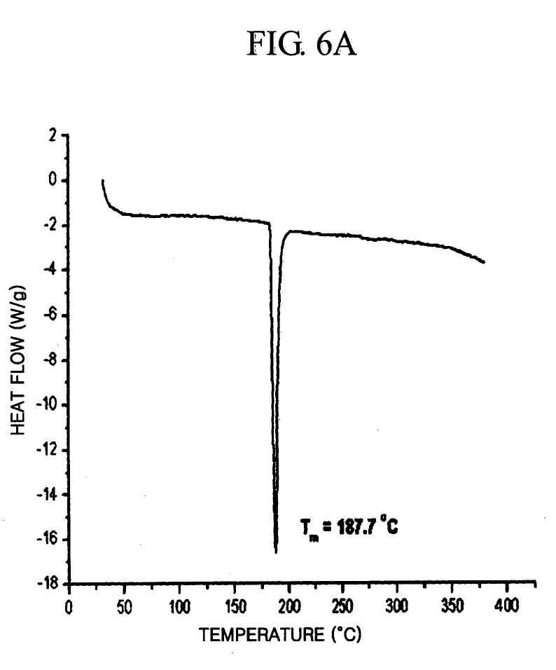

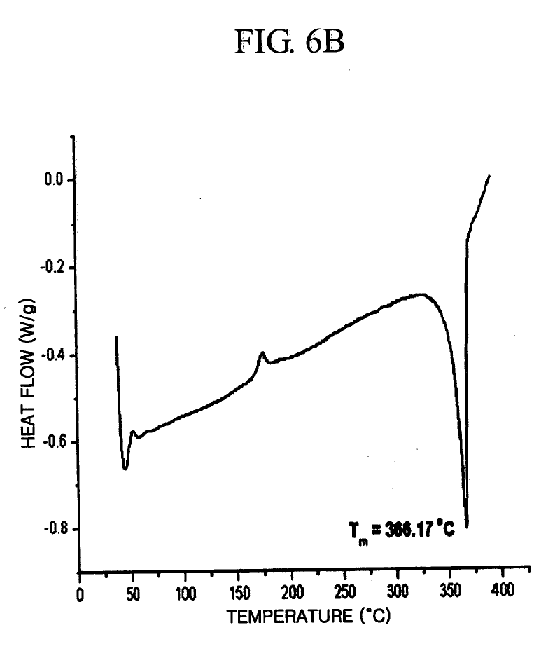

The results of DSC of m-CP and the compound represented by Formula A are illustrated in FIGS. 6A and 6B, respectively. The melting point (Tₘ) of m-CP was about 187.7° C., and The melting point (Tₘ) of the compound represented by Formula A was about was about 366.17° C.

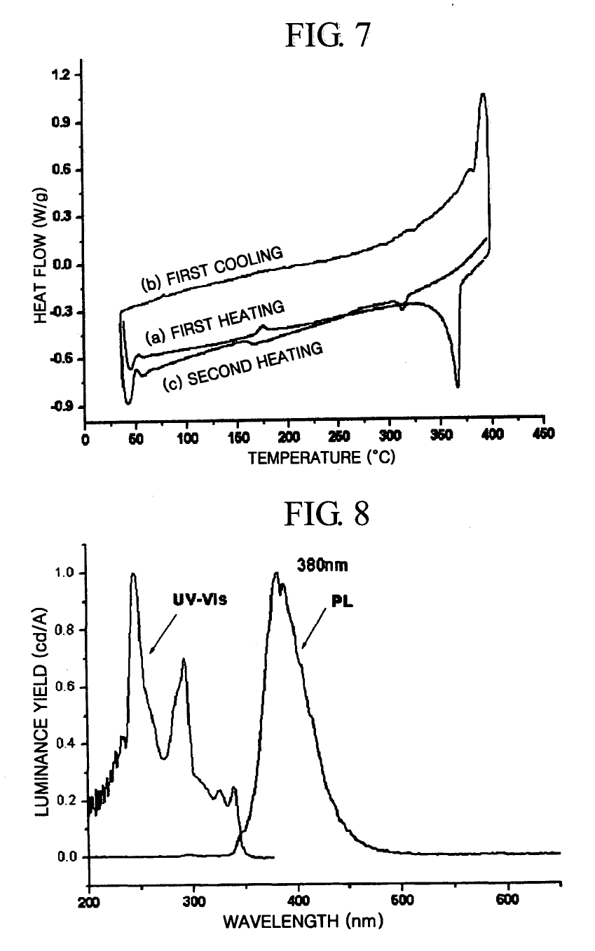

Referring to FIG. 7, after the compound represented by Formula A melted at about 370° C., it was not recrystallized or did not melt again when re-cooled and re-heated.

Based on these results, it can be seen that the compound represented by

Formula A was superior to m-CP in terms of thermal stability.

The compounds represented by Formulae B through D had the same

characteristics as the compound represented by Formula A. Such results are assumed to result from the structures of the compounds represented by Formulae A through D. That is, bulky substituents are positioned in outer portions of the compounds represented by Formulae A through D and thus three-dimensional obstruction occurs when these compounds are crystallized. Due to such a structure, they can be remained amorphous state after being melting once.

In order to measure optical characteristics of the compound represented by Formula A according to Synthesis Example, the compound represented by Formula A was dissolved in chloroform and measured using a UV-VIS spectrum and a photoluminescence (PL) spectrum. The results are shown in FIG. 8.

Referring to FIG. 8, UV-VIS peaks of the compound represented by Formula A appeared at 245 nm and 291 nm, and 291 nm PL spectrum peaks of the compound represented by Formula A appeared at 406 nm at maximum.

As described above, the compounds A through D, in particular, the compound represented by Formula A can be used as a phosphorescent host material of an organic EL device due to its excellent thermal stability.

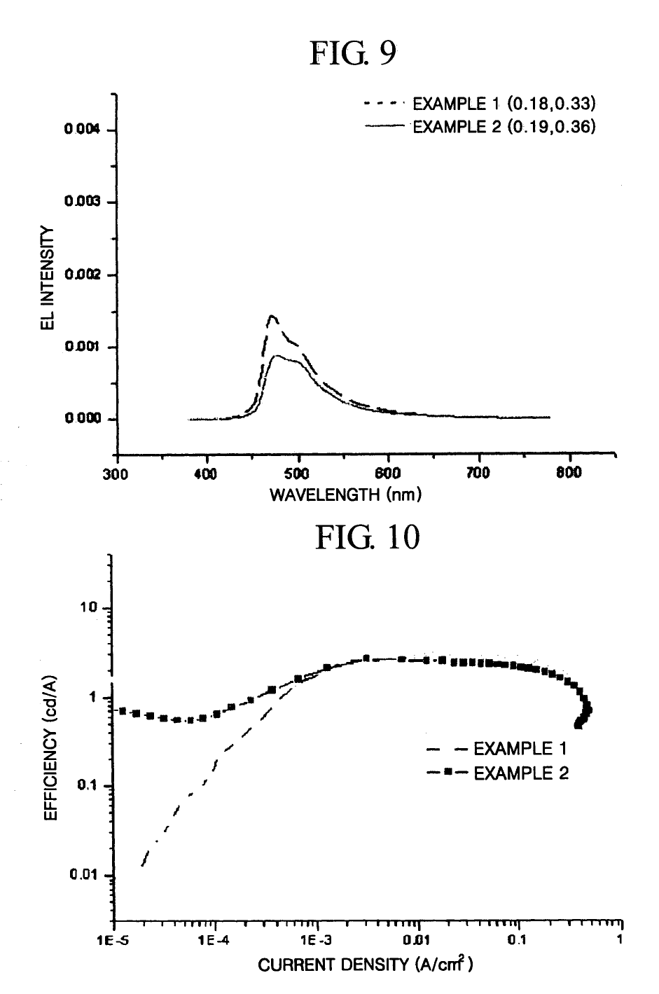

Various characteristics of OLED prepared using TCBP, which is the phosphorescent host material according to embodiments of the present invention, were measured, and the results are shown in FIGS. 9 through 11.

Manufacture of Organic EL Device

### Example 1

An indium-tin oxide (ITO)-coated transparent electrode substrate 20 was washed and formed in a pattern using a photoresist resin and an etchant, thus forming an ITO electrode pattern 10. The ITO electrode pattern 10 was washed, and PEDOT{poly(3,4-ethylenedioxythiophene)}[Al 4083] was coated thereon to a thickness of about 50 nm and baked at 180° C. for about 1 hour, thus forming a hole injection layer 11.

An emission layer forming composition that was prepared by mixing 29 mg of TCBP and 2.5 mg of phosphorescent iridium complex iridium(III)bis[(4,6-difluorophenyl)-pyridinato-N,C^{2l}]picolinate (Firpic) in a 3.3 g of a polystyrene (PS) solution, which was obtained by dissolving 5.31 g of PS in 17.4 g of toluene, was spin coated on the hole injection layer 11, baked at 90° C. for 2 hours, and placed in a vacuum oven to completely remove the solvent, thus forming an emission layer 12 with a thickness of 40 nm [PS 24 wt %, TCBP 70 wt %, Firpic 6 wt %].

Then, BAlq was vacuum deposited on the polymer emission layer 12 under a pressure of 4×10⁻⁶ torr or less to form an electron transport layer 15 with a thickness of 40 nm. LiF was deposited at 0.1 Å/sec on the electron transport layer 15 to form an electron injection layer with a thickness of 10 nm.

Then, Al was deposited at 10 Å/sec to form a cathode 14 with a thickness of 200 nm and encapsulated using a metal can with BaO powder in a glove box under a dry nitrogen gas atmosphere, and then treated with UV curing agent, thus completely manufacturing an organic EL device.

The EL device has a multi-layered structure, and its schematic structure is illustrated in FIG. 12. The emission area of the EL device was 6 mm².

### Example 2

An indium-tin oxide (ITO)-coated transparent electrode substrate 20 was washed and formed in a pattern using a photoresist resin and an etchant, thus forming an ITO electrode pattern 10. The ITO electrode pattern 10 was washed, and PEDOT{poly(3,4-ethylenedioxythiophene)}[Al 4083] was coated thereon to a thickness of about 50 nm and baked at 180° C. for about 1 hour, thus forming a hole injection layer 11.

An emission layer forming composition that was prepared by mixing 39 mg of TCBP and 2.5 mg of Firpic in 2.0 g of toluene was spin coated on the hole injection layer 11, baked at 90° C. for 2 hours, and placed in a vacuum oven to completely remove the solvent, thus forming an emission layer 12 with a thickness of 40 nm.

Then, BAlq was vacuum deposited on the polymer emission layer 12 under a pressure of 4×10⁻⁶ torr or less to form an electron transport layer 15 with a thickness of 40 nm. LiF was deposited at 0.1 Å/sec on the electron transport layer 15 to form an electron injection layer with a thickness of 10 nm.

Then, Al was deposited at 10 Å/sec to form an anode 14 with a thickness of 200 nm and encapsulated using a metal can with BaO powder in a glove box under a dry nitrogen gas atmosphere, and then treated with UV curing agent, thus completely manufacturing an organic EL device.

The EL device has a multi-layered structure, and its schematic structure is illustrated in FIG. 12. The emission area of the EL device was 6 mm².

The color coordinate and EL characteristics of the organic EL devices according to Examples 1 and 2 were measured and the results are shown in FIGS. 9 through 11. EL characteristics were measured using a forward bias voltage (SMU238 obtained from Keithley Co.), which is a current voltage as a driving voltage. Luminosity, spectrum, and color coordinate characteristics were measure using PR 650 (obtained from Photo Research Co.)

Referring to FIG. 9, polystyrene was used in Example 1, but was not used in Example 2. That is, only the compound represented by Formula A (TBCP) was used in Example 2. As illustrated in FIG. 9, similar effects could be obtained even when polystyrene was not used as a matrix polymer.

FIG. 10 illustrates efficiency of the organic EL devices according to Examples 1 and 2 manufactured using the compound represented by Formula A (TCBP). The organic EL devices according to Examples 1 and 2 had similar characteristics. As illustrated in FIG. 10, similar effects were obtained even when polystyrene was not used as a matrix polymer, and thus, a solution process could be used to manufacture organic EL devices.

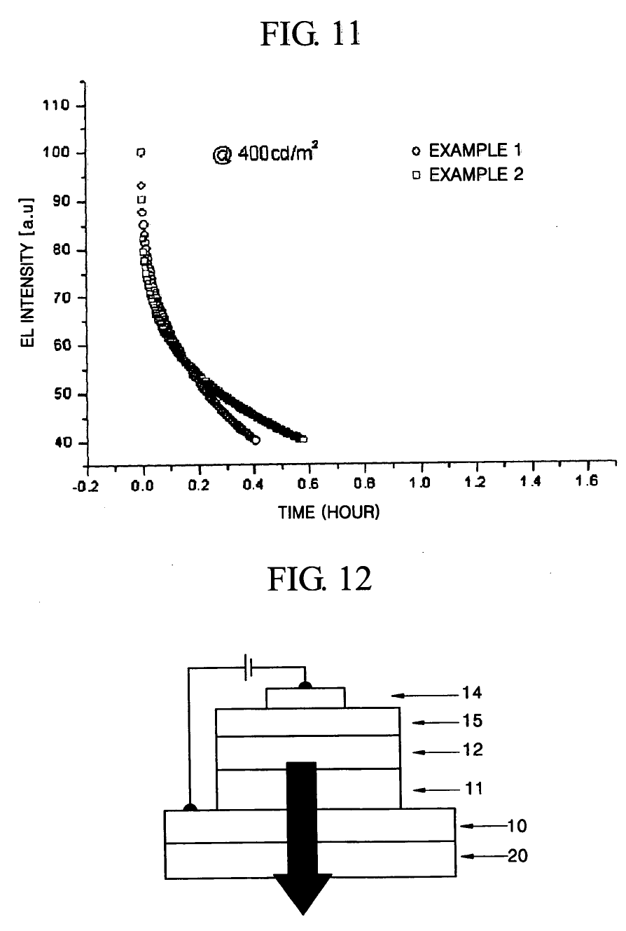

Referring to FIG. 11, the organic EL device according to Example 2 in which polystyrene was not used and the solution process was used exhibited a longer lifetime than the organic EL device according to Example 1.

As stated above, the host material according to an embodiment of the present invention produces the same effects without the matrix polymer, which is confirmed by FIGS. 9 to 11.

As described above, an emission layer according to the present invention is composed of a phosphorescent host material having a structure in which four substituents are pendent to 3,5,3′, and 5′ positions of biphenyl, which is a backbone. As a result, an organic EL device including the emission layer exhibits excellent thermal stability, excellent crystal stability, ease of film formation, and luminosity with high efficiency.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A biphenyl derivative represented by Formula 1: 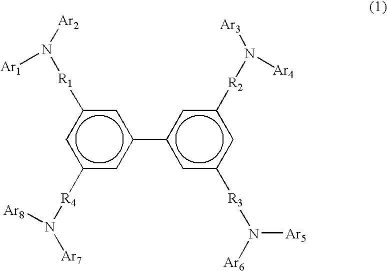
where R₁, R₂, R₃, and R₄ are each independently a single bond, a substituted or non-substituted linear or branched C₁-C₂₀ alkyl group, a substituted or non-substituted C₃-C₂₀ cycloalkyl group, a substituted or non-substituted C₁-C₁₀ alkenyl group; a substituted or non-substituted C₁-C₁₀ alkynyl group, a substituted or non-substituted C₄-C₃₀ aryl group, a substituted or non-substituted C₄-C₃₀ heteroaryl group, or a C₄-C₃₀ aryl group having at least one substituent, said substituent selected from the group consisting of a halogen atom, a substituted or non-substituted C₁-C₂₀ alkyl halide group, —Si(R)(R′)(R″), a substituted or non-substituted C₁-C₂₀ alkyl group, a substituted or non-substituted C₁-C₂₀ alkoxy group, a substituted or non-substituted C₄-C₃₀ aryl group, a substituted or non-substituted C₄-C₃₀ heteroaryl group, and —N(R)(R′), and
Ar₁, Ar₂, Ar₃, Ar₄, Ar₅, Ar₆, Ar₇, and Ar₈ are each independently H, a substituted or non-substituted linear or branched C₁-C₂₀ alkyl group, a substituted or non-substituted C₃-C₂₀ cycloalkyl group; a substituted or non-substituted C₄-C₃₀ aryl group; a substituted or non-substituted C₄-C₃₀ heteroaryl group; or a C₄-C₃₀ aryl group having at least one substituent selected from the group consisting of a substituted or non-substituted C₁-C₂₀ alkyl halide group, —Si(R)(R′)(R″), a substituted or non-substituted C₁-C₂₀ alkyl group, a substituted or non-substituted C₁-C₂₀ alkoxy group, a substituted or non-substituted C₄-C₃₀ aryl group, a substituted or non-substituted C₄-C₃₀ heteroaryl group, and —N(R)(R′), wherein Ar₁ can be connected to Ar₂, Ar₃ can be connected to Ar₄, Ar₅ can be connected to Ar₆, and Ar₇ can be connected to Ar₈; and
R, R′, and R″ are each independently H, a substituted or non-substituted C₁-C₂₀ alkyl group, a substituted or non-substituted C₁-C₂₀ alkoxy group, a substituted or non-substituted C₄-C₃₀ aryl group, or a substituted or non-substituted C₄-C₃₀ heteroaryl group.

2. The biphenyl derivative of claim 1, wherein —N(Ar₁)(Ar₂), —N(Ar₃)(Ar₄), —N(Ar₅)(Ar₆), and —N(Ar₇)(Ar₈) are each independently a group represented by Formula 2: 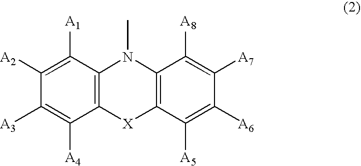
where X is —(CH₂)ₙ— where n is an integer between 0 and 2, —C(R₅)(R₆)—, —CH═CH—, —S—, —O—, or —Si(R₅)(R₆)—, and
A₁, A₂, A₃, A₄, A₅, A₆, A₇, A₈, R₅, and R₆ are each independently H; deuterium; a cyano group; a nitro group; a substituted or non-substituted linear or branched C₁-C₂₀ alkyl group; a substituted or non-substituted C₃-C₂₀ cycloalkyl group; a substituted or non-substituted C₄-C₃₀ aryl group; a substituted or non-substituted C₄-C₃₀ heteroaryl group; or a C₄-C₃₀ aryl group having at least one substituent selected from the group consisting of a C₁-C₂₀ alkyl halide group, —Si(R)(R′)(R″), a substituted or non-substituted C₁-C₂₀ alkyl group, a substituted or non-substituted C₁-C₂₀ alkoxy group, a substituted or non-substituted C₄-C₃₀ aryl group, a substituted or non-substituted C₄-C₃₀ heteroaryl group, and —N(R)(R′), wherein A₁ can be connected to A₂, A₂ can be connected to A₃, A₃ can be connected to A₄, A₅ can be connected to A₆, A₆ can be connected to A₇, and A₇ can be connected to A₈; and
R, R′, and R″ are each independently H, a substituted or non-substituted C₁-C₂₀ alkyl group, a substituted or non-substituted C₁-C₂₀ alkoxy group, a substituted or non-substituted C₄-C₃₀ aryl group, or a substituted or non-substituted C₄-C₃₀ heteroaryl group.

3. The biphenyl derivative of claim 1, wherein —N(Ar₁)(Ar₂), —N(Ar₃)(Ar₄), —N(Ar₅)(Ar₆), and —N(Ar₇)(Ar₈) are each independently selected from the group consisting of groups represented by Formulae 2a through 2h: 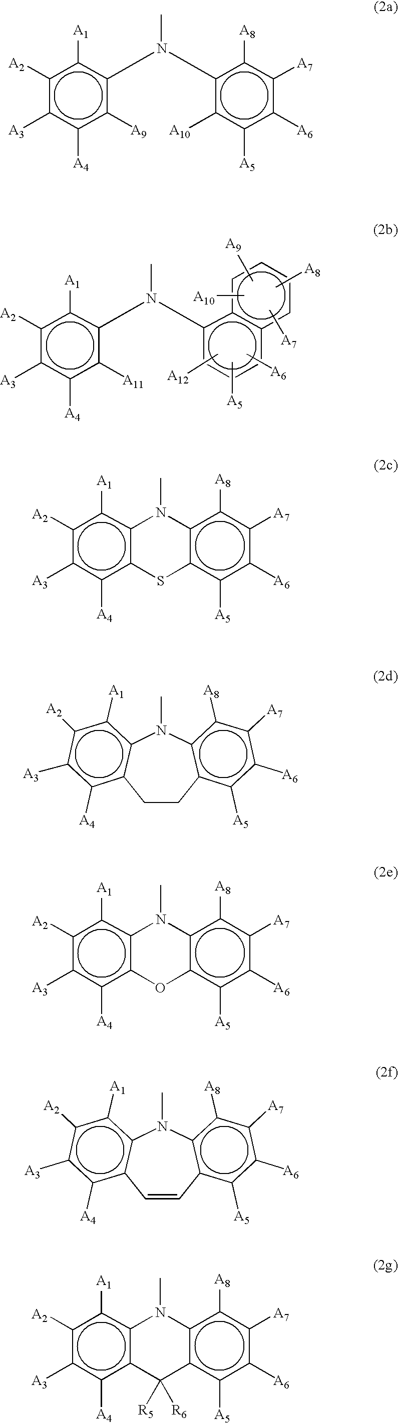 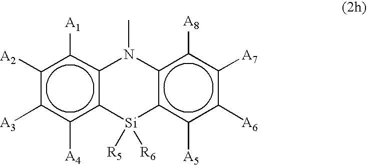
where A₁, A₂, A₃, A₄, A₅, A₆, A₇, A₈, A₉, A₁₀, A₁₁, A₁₂, R₅, and R₆ are each independently H; deuterium; a cyano group; a nitro group; a substituted or non-substituted linear or branched C₁-C₂₀ alkyl group; a substituted or non-substituted C₃-C₂₀ cycloalkyl group; a substituted or non-substituted C₁-C₁₀ alkenyl group; a substituted or non-substituted alkynyl group; a substituted or non-substituted C₄-C₃₀ aryl group; a substituted or non-substituted C₄-C₃₀ heteroaryl group; or a C₄-C₃₀ aryl group having at least one substituent selected from the group consisting of a C₁-C₂₀ alkyl halide group, —Si(R)(R′)(R″), a substituted or non-substituted C₁-C₂₀ alkyl group, a substituted or non-substituted C₁-C₂₀ alkoxy group, a substituted or non-substituted C₄-C₃₀ aryl group, a substituted or non-substituted C₄-C₃₀ heteroaryl group, and —N(R)(R′), wherein A₁ can be connected to A₂, A₂ can be connected to A₃, A₃ can be connected to A₄, A₅ can be connected to A₆, A₆ can be connected to A₇, and A₇ can be connected to A₈; and
R, R′, and R″ are each independently H, a substituted or non-substituted C₁-C₂₀ alkyl group, a substituted or non-substituted C₁-C₂₀ alkoxy group, a substituted or non-substituted C₄-C₃₀ aryl group, or a substituted or non-substituted C₄-C₃₀ heteroaryl group.

4. The biphenyl derivative of claim 1, wherein —N(Ar₁)(Ar₂), —N(Ar₃)(Ar₄), —N(Ar₅)(Ar₆), and —N(Ar₇)(Ar₈) are each independently a group represented by Formula 3: 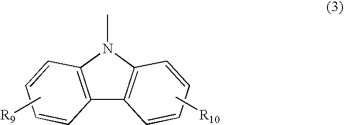
where R₉ and R₁₀ are each independently H; deuterium; a cyano group; a nitro group; a substituted or non-substituted linear or branched C₁-C₂₀ alkyl group; a substituted or non-substituted C₃-C₂₀ cycloalkyl group; a substituted or non-substituted C₄-C₃₀ aryl group; a substituted or non-substituted C₄-C₃₀ heteroaryl group; or a C₄-C₃₀ aryl group having at least one substituent selected from the group consisting of a C₁-C₂₀ alkyl halide group, —Si(R)(R′)(R″), a substituted or non-substituted C₁-C₂₀ alkyl group, a substituted or non-substituted C₁-C₂₀ alkoxy group, a substituted or non-substituted C₄-C₃₀ aryl group, a substituted or non-substituted C₄-C₃₀ heteroaryl group, and —N(R)(R′), wherein R, R′, and R″ are each independently H, a substituted or non-substituted C₁-C₂₀ alkyl group, a substituted or non-substituted C₁-C₂₀ alkoxy group, a substituted or non-substituted C₄-C₃₀ aryl group, or a substituted or non-substituted C₄-C₃₀ heteroaryl group.

5. The biphenyl derivative of claim 1, wherein —R₁N(Ar₁)(Ar₂), —R₂N(Ar₃)(Ar₄), —R₃N(Ar₅)(Ar₆), and —R₄N(Ar₇)(Ar₈) of Formula 1 are each independently a group represented by Formula 5: 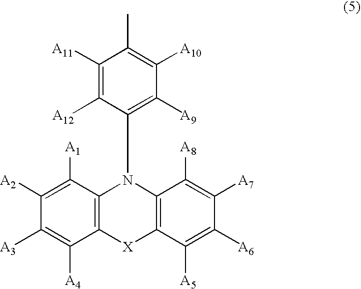
where X is —(CH₂)ₙ— where n is an integer between 0 and 2, —C(R₅)(R₆)—, —CH═CH—, —S—, —O—, or —Si(R₅)(R₆)—, and
A₁, A₂, A₃, A₄, A₅, A₆, A₇, A₈, A₉, A₁₀, A₁₁, A₁₂, R₅, and R₆ are each independently H; deuterium; a cyano group; a nitro group; a substituted or non-substituted linear or branched C₁-C₂₀ alkyl group; a substituted or non-substituted C₃-C₂₀ cycloalkyl group; a substituted or non-substituted C₄-C₃₀ aryl group; a substituted or non-substituted C₄-C₃₀ heteroaryl group; or a C₄-C₃₀ aryl group having at least one substituent selected from the group consisting of a C₁-C₂₀ alkyl halide group, —Si(R)(R′)(R″), a substituted or non-substituted C₁-C₂₀ alkyl group, a substituted or non-substituted C₁-C₂₀ alkoxy group, a substituted or non-substituted C₄-C₃₀ aryl group, a substituted or non-substituted C₄-C₃₀ heteroaryl group, and —N(R)(R′), wherein A₁ can be connected to A₂, A₂ can be connected to A₃, A₃ can be connected to A₄, A₅ can be connected to A₆, A₆ can be connected to A₇, A₇ can be connected to A₈, A₉ can be connected to A₁₀, and A₁₁ can be connected to A₁₂; and
R, R′, and R″ are each independently H, a substituted or non-substituted C₁-C₂₀ alkyl group, a substituted or non-substituted C₁-C₂₀ alkoxy group, a substituted or non-substituted C₄-C₃₀ aryl group, or a substituted or non-substituted C₄-C₃₀ heteroaryl group.

6. The biphenyl derivative of claim 1, wherein —R₁N(Ar₁)(Ar₂), —R₂N(Ar₃)(Ar₄), —R₃N(Ar₅)(Ar₆), and —R₄N(Ar₇)(Ar₈) of Formula 1 are each independently selected from the group consisting of groups represented by Formulae 3a through 3h: 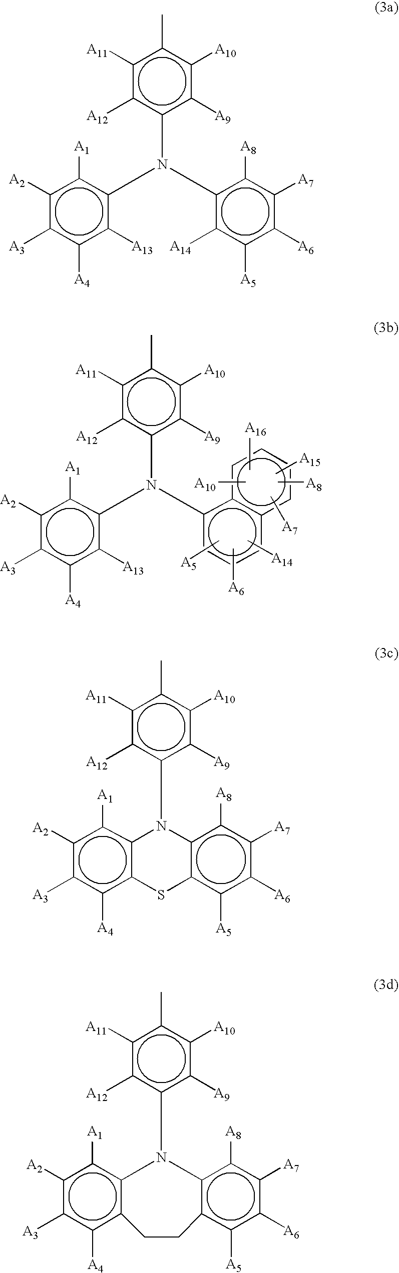 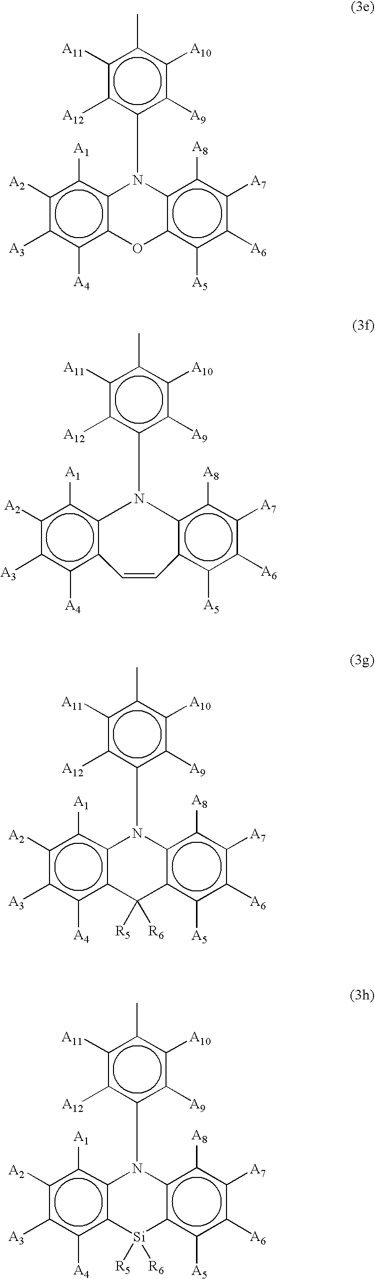
where A₁, A₂, A₃, A₄, A₅, A₆, A₇, A₈, A₉, A₁₀, A₁₁, A₁₂, A₁₃, A₁₄, A₁₅, A₁₆, R₅, and R₆ are each independently H; deuterium; a cyano group; a nitro group; a substituted or non-substituted linear or branched C₁-C₂₀ alkyl group; a substituted or non-substituted C₃-C₂₀ cycloalkyl group; a substituted or non-substituted C₄-C₃₀ aryl group; a substituted or non-substituted C₄-C₃₀ heteroaryl group; or a C₄-C₃₀ aryl group having at least one substituent selected from the group consisting of a C₁-C₂₀ alkyl halide group, —Si(R)(R′)(R″), a substituted or non-substituted C₁-C₂₀ alkyl group, a substituted or non-substituted C₁-C₂₀ alkoxy group, a substituted or non-substituted C₄-C₃₀ aryl group, a substituted or non-substituted C₄-C₃₀ heteroaryl group, and —N(R)(R′), wherein A₁ can be connected to A₂, A₂ can be connected to A₃, A₃ can be connected to A₄, A₅ can be connected to A₆, A₆ can be connected to A₇, A₇ can be connected to A₈, A₉ can be connected to A₁₀, and A₁₁ can be connected to A₁₂; and
R, R′, and R″ are each independently H, a substituted or non-substituted C₁-C₂₀ alkyl group, a substituted or non-substituted C₁-C₂₀ alkoxy group, a substituted or non-substituted C₄-C₃₀ aryl group, or a substituted or non-substituted C₄-C₃₀ heteroaryl group.

7. The biphenyl derivative of claim 5, wherein —R₁N(Ar₁)(Ar₂), —R₂N(Ar₃)(Ar₄), —R₃N(Ar₅)(Ar₆), and —R₄N(Ar₇)(Ar₈) of Formula 1 are each independently a group represented by Formula 6: 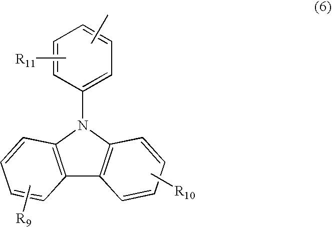
where R₉, R₁₀, and R₁₁ are each independently H; deuterium; a cyano group; a nitro group; a substituted or non-substituted linear or branched C₁-C₂₀ alkyl group; a substituted or non-substituted C₃-C₂₀ cycloalkyl group; a substituted or non-substituted C₄-C₃₀ aryl group; a substituted or non-substituted C₄-C₃₀ heteroaryl group; or a C₄-C₃₀ aryl group having at least one substituent selected from the group consisting of a C₁-C₂₀ alkyl halide group, —Si(R)(R′)(R″), a substituted or non-substituted C₁-C₂₀ alkyl group, a substituted or non-substituted C₁-C₂₀ alkoxy group, a substituted or non-substituted C₄-C₃₀ aryl group, a substituted or non-substituted C₄-C₃₀ heteroaryl group, and —N(R)(R′), wherein R, R′, and R″ are each independently H, a substituted or non-substituted C₁-C₂₀ alkyl group, a substituted or non-substituted C₁-C₂₀ alkoxy group, a substituted or non-substituted C₄-C₃₀ aryl group, or a substituted or non-substituted C₄-C₃₀ heteroaryl group.

8. The biphenyl derivative of claim 7, wherein each of R₉, R₁₀, and R₁₁ of Formula 6 is represented by Formula 4: 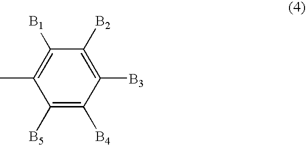
where B₁, B₂, B₃, B₄, and B₅ are each independently each independently H; deuterium; a cyano group; a nitro group; a substituted or non-substituted linear or branched C₁-C₂₀ alkyl group; a substituted or non-substituted C₃-C₂₀ cycloalkyl group; a substituted or non-substituted C₄-C₃₀ aryl group; a substituted or non-substituted C₄-C₃₀ heteroaryl group; or a C₄-C₃₀ aryl group having at least one substituent selected from the group consisting of a C₁-C₂₀ alkyl halide group, —Si(R)(R′)(R″), a substituted or non-substituted C₁-C₂₀ alkyl group, a substituted or non-substituted C₁-C₂₀ alkoxy group, a substituted or non-substituted C₄-C₃₀ aryl group, a substituted or non-substituted C₄-C₃₀ heteroaryl group, and —N(R)(R′), wherein R, R′, and R″ are each independently H, a substituted or non-substituted C₁-C₂₀ alkyl group, a substituted or non-substituted C₁-C₂₀ alkoxy group, a substituted or non-substituted C₄-C₃₀ aryl group, or a substituted or non-substituted C₄-C₃₀ heteroaryl group.

9. The biphenyl derivative of claim 1 represented by one selected from the group consisting of Formulae A through D:

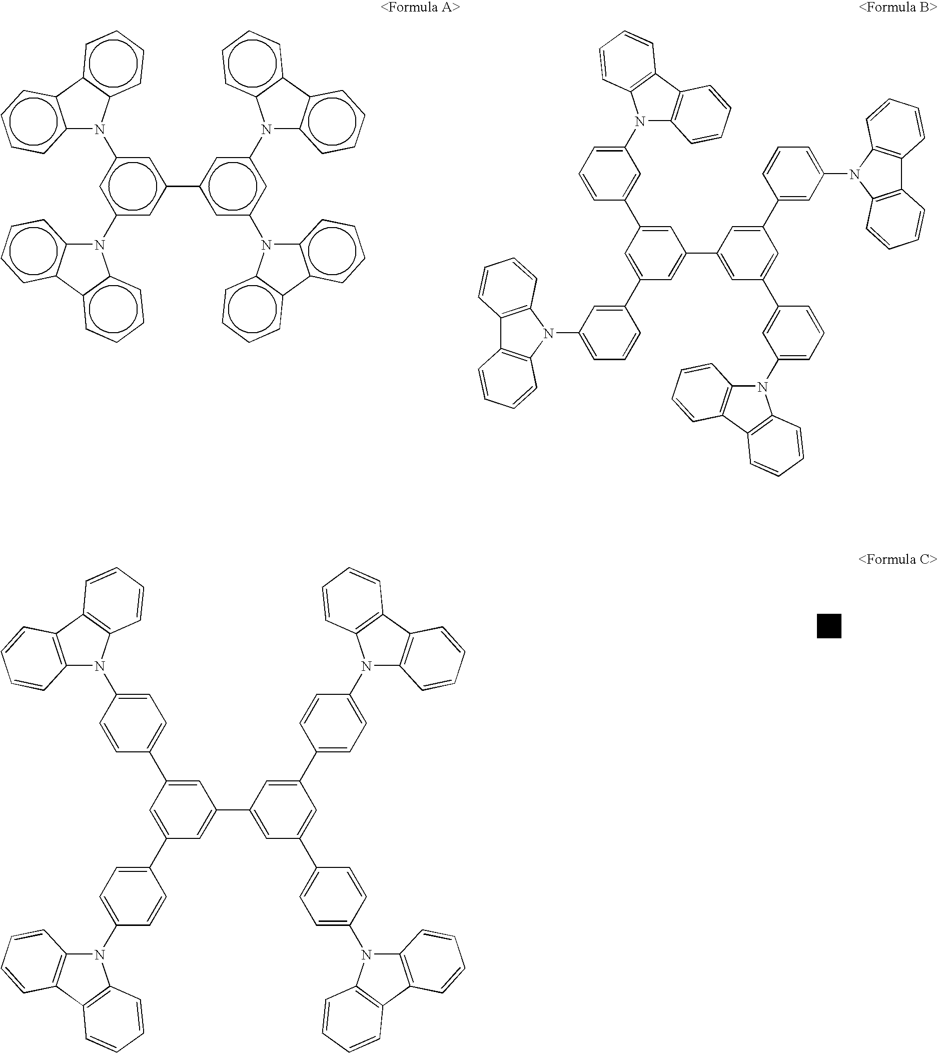

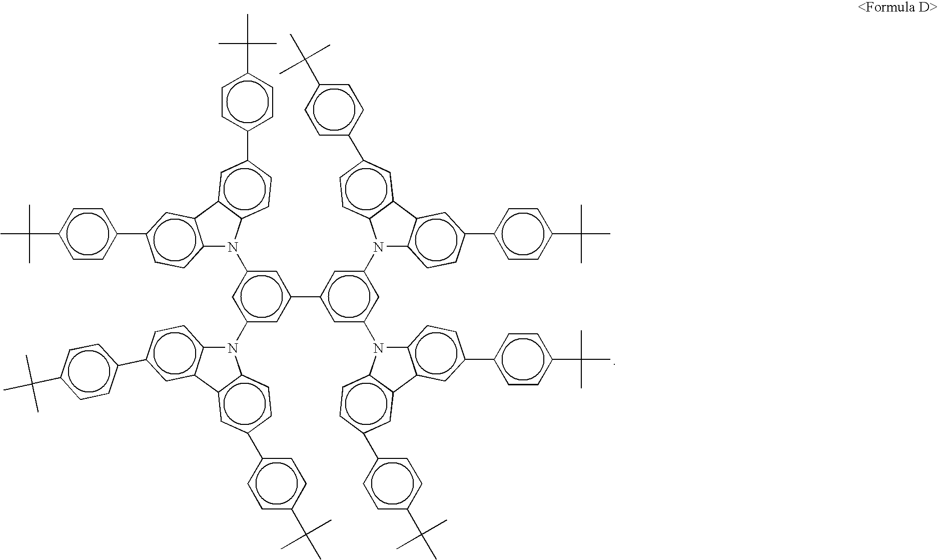

10. An organic electroluminescent device having an organic layer composed of the biphenyl derivative of claim 1.

11. The organic electroluminescent device of claim 10, wherein the organic layer is one of an emission layer, a hole transport layer, and a hole injection layer.

12. The organic electroluminescent device of claim 10, wherein the organic layer is the emission layer that is composed of 70 to 99.9% by weight of the biphenyl derivative and 0.1 to 30% by weight of a dopant.

13. An organic electroluminescent device, comprising:
a pair of electrodes; and
an organic layer interposed between the pair of electrodes, the organic layer being composed of a phosphorescent host material having a structure in which four substituents are pendent to 3,3′,5,5′ positions of a biphenyl backbone.

14. The organic electroluminescent device of claim 13, wherein the host material is 3,3′,5,5′-tetra(9H-carbazol-9-yl)biphenol.

15. An organic electroluminescent device, comprising:
a pair of electrodes; and
an organic layer interposed between the pair of electrodes, the organic layer being composed of a biphenyl derivative represented by Formula 1: 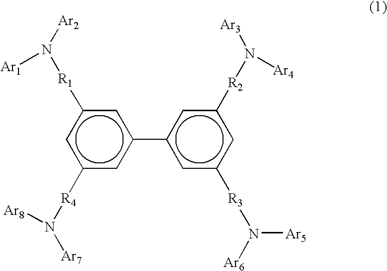
where R₁, R₂, R₃, and R₄ are each independently a single bond, a substituted or non-substituted linear or branched C₁-C₂₀ alkyl group, a substituted or non-substituted C₃-C₂₀ cycloalkyl group, a substituted or non-substituted C₁-C₁₀ alkenyl group; a substituted or non-substituted C₁-C₁₀ alkynyl group, a substituted or non-substituted C₄-C₃₀ aryl group, a substituted or non-substituted C₄-C₃₀ heteroaryl group, or a C₄-C₃₀ aryl group having at least one substituent, said substituent selected from the group consisting of a halogen atom, a substituted or non-substituted C₁-C₂₀ alkyl halide group, —Si(R)(R′)(R″), a substituted or non-substituted C₁-C₂₀ alkyl group, a substituted or non-substituted C₁-C₂₀ alkoxy group, a substituted or non-substituted C₄-C₃₀ aryl group, a substituted or non-substituted C₄-C₃₀ heteroaryl group, and —N(R)(R′), and
Ar₁, Ar₂, Ar₃, Ar₄, Ar₅, Ar₆, Ar₇, and Ar₈ are each independently H, a substituted or non-substituted linear or branched C₁-C₂₀ alkyl group, a substituted or 19 non-substituted C₃-C₂₀ cycloalkyl group; a substituted or non-substituted C₄-C₃₀ aryl group; a substituted or non-substituted C₄-C₃₀ heteroaryl group; or a C₄-C₃₀ aryl group having at least one substituent selected from the group consisting of a substituted or non-substituted C₁-C₂₀ alkyl halide group, —Si(R)(R′)(R′), a substituted or non-substituted C₁-C₂₀ alkyl group, a substituted or non-substituted C₁-C₂₀ alkoxy group, a substituted or non-substituted C₄-C₃₀ aryl group, a substituted or non-substituted C₄-C₃₀ heteroaryl group, and —N(R)(R′), wherein Ar₁ can be connected to Ar₂, Ar₃ can be connected to Ar₄, Ar₅ can be connected to Ar₆, and Ar₇ can be connected to Ar₈; and
R, R′, and R″ are each independently H, a substituted or non-substituted C₁-C₂₀ alkyl group, a substituted or non-substituted C₁-C₂₀ alkoxy group, a substituted or non-substituted C₄-C₃₀ aryl group, or a substituted or non-substituted C₄-C₃₀ heteroaryl group.

16. The organic electroluminescent device of claim 15, wherein the organic layer comprises an emission layer, optionally a hole transport layer, and optionaolly a hole injection layer.

17. The organic electroluminescent device of claim 15, wherein the organic layer is an emission layer composed of 70 to 99.9% by weight of the biphenyl derivative and 0.1 to 30% by weight of a dopant.

18. The organic electroluminescent device of claim 15, wherein the biphenyl derivative is 3,3′,5,5′-tetra(9H-carbazol-9-yl)biphenol.

19. The organic electroluminescent device of claim 15, wherein the organic layer is formed by a solution process.

20. The organic electroluminescent device of claim 19, wherein a matrix polymer is not used in the solution process.
